(19) United States
(12) Patent Application Publication
(10) Pub. No.: US 2026/0064273 A1
(43) Pub. Date: Mar. 5, 2026

(54) METHOD, COMPRESSION ENCODER, AND COMPRESSION/DECOMPRESSION SYSTEM

(71) Applicant: Kioxia Corporation, Tokyo (JP)

(72) Inventors: Youhei FUKAZAWA, Yokohama (JP); Kohei OIKAWA, Yokohama (JP); Keiri NAKANISHI, Kawasaki (JP); Masato SUMIYOSHI, Yokohama (JP)

(73) Assignee: Kioxia Corporation, Tokyo (JP)

(21) Appl. No.: 19/069,591

(22) Filed: Mar. 4, 2025

(30) Foreign Application Priority Data
Aug. 28, 2024 (JP) 2024-146507

(51) Int. Cl. G06F 3/06

(52) U.S. Cl. CPC G06F 3/0608; G06F 3/0659; G06F 3/0679

(57) ABSTRACT

According to one embodiment, a method includes identifying an input string of less than the predetermined length as a mismatch character string, determining whether the mismatch character string matches the character strings in a buffer, storing, as to the matched mismatch character string, a first data set including flag information indicating a match and index information indicating the entry of the buffer in which the mismatch character string determined to be a match is stored, in a nonvolatile memory, and storing the unmatched mismatch character string in the buffer, and storing, as to the unmatched mismatch character string, a second data set including flag information indicating the mismatch and the mismatch character strings, in the nonvolatile memory.

### CROSS-REFERENCE TO RELATED APPLICATIONS

This application is based upon and claims the benefit of priority from Japanese Patent Application No. 2024-146507, filed Aug. 28, 2024, the entire contents of which are incorporated herein by reference.

### FIELD

Embodiments described herein relate generally to a method, compression encoder, and compression/decompression system.

### BACKGROUND

In data centers, for example, when storing large amounts of user data, if the data is stored in its original form, the capacity of data storage devices such as hard disk drives (HDDs) and solid state drives (SSDs) is overwhelmed, and the costs associated with these devices increase. Therefore, lossless compression is generally used to reduce the amount of data.

Data reduction methods generally incorporate a compression technique which combines dictionary type compression and entropy encoding. The dictionary type compression of gzip, which is typical of these compression methods, has a dictionary which holds data sequences that have appeared in the past, searches the dictionary for data sequences matching the data sequence to be compressed, and if the dictionary holds a matching data sequence, converts the data sequence to be compressed into the address and match length of the dictionary. The data is then compressed by entropy encoding the address and match length of the dictionary or the mismatched data sequence to reduce the data volume. By reducing the data volume in this way, more data can be written to the data storage device. Here, the address of the dictionary is the storage position of the dictionary where the matched data sequence is stored, and is referred to as the match distance. The match length is the length of the matched data sequence. The match length is indicated, for example, by the number of characters (one character corresponds to 8 bits).

By the way, when the dictionary match of dictionary type compression (LZSS: Lempel-Ziv-Storer-Szymanski) is expressed as (match length, match distance), if match lengths is 2 (2 characters: 16 bits) to 3 (3 characters: 24 bits), it is often better to output the mismatched characters as they are to reduce the data volume. For example, assuming a dictionary size of 4 KByte and a maximum match length of 256, the total data volume for a dictionary match is 23 bits (match information (1 bit), match length (8 bits), and match distance (12 bits)), which conversely increases for match length 2 or less. Therefore, the minimum match length is often set to 3 to 4 for dictionary type compression.

### BRIEF DESCRIPTION OF THE DRAWINGS

FIG. 1 is a diagram showing an example of a configuration of a memory system of the first embodiment.

FIG. 2 is a diagram showing an example of a configuration of a compressor of the memory system of the first embodiment.

FIG. 3 is a diagram for explaining an overview of an operation of the compressor of the memory system of the first embodiment.

FIG. 4 is a diagram for further explaining the overview of the operation of the compressor of the memory system of the first embodiment, by showing an example.

FIG. 5 is a flowchart showing an operating procedure of the compressor of the memory system of the first embodiment.

FIG. 6 is a diagram showing an example of a configuration of a decompressor of the memory system of the first embodiment.

FIG. 7 is a diagram for explaining an overview of an operation of the decompressor of the memory system of the first embodiment.

FIG. 8 is a flowchart showing an operating procedure of the decompressor of the memory system of the first embodiment.

FIG. 9 is a flowchart showing an operating procedure of a compressor of a memory system of a second embodiment.

FIG. 10 is a flowchart showing an operating procedure of the decompressor of the memory system of the second embodiment.

FIG. 11 is a diagram showing an example of a configuration of a compressor of a memory system of a third embodiment.

FIG. 12 is a diagram showing a concept of updating a character buffer of the memory system of the third embodiment.

FIG. 13 is a flowchart showing an operating procedure of the compressor of the memory system of the third embodiment.

FIG. 14 is a diagram showing an example of a configuration of the decompressor of the memory system of the third embodiment.

FIG. 15 is a flowchart showing an operating procedure of the decompressor of the memory system of the third embodiment.

FIG. 16 is a diagram showing an example of a configuration of a compressor of a memory system of a fourth embodiment.

FIG. 17 is a diagram showing a concept of updating a character buffer of the memory system of the fourth embodiment.

FIG. 18 is a flowchart showing an operating procedure of a compressor of the memory system of the fourth embodiment.

FIG. 19 is a diagram showing an example of a configuration of a decompressor of the memory system of the fourth embodiment.

FIG. 20 is a flowchart showing an operating procedure of the decompressor of the memory system of the fourth embodiment.

FIG. 21 is a diagram showing an example of a configuration of a compressor in a memory system of a fifth embodiment.

FIG. 22 is a diagram showing a concept of updating a character buffer of the memory system of the fifth embodiment.

FIG. 23 is a flowchart showing an operating procedure of the compressor of the memory system of the fifth embodiment.

FIG. 24 is a diagram showing an example of a configuration of a decompressor of the memory system of the fifth embodiment.

FIG. 25 is a flowchart showing an operating procedure of the decompressor of the memory system of the fifth embodiment.

### DETAILED DESCRIPTION

In general, according to one embodiment, a method of controlling a nonvolatile memory includes: outputting information indicating a result of comparison between an input string of a predetermined length or longer and a string which has appeared previously as compressed data; storing data based on the output compressed data in the nonvolatile memory; identifying an input string of less than the predetermined length as a mismatch character string; determining whether or not the identified mismatch character string matches one of the mismatch character strings in the buffer where the mismatch character strings that have appeared previously are stored; storing, as to the identified mismatch character string matching any of the mismatch character strings in the buffer, data based on a first data set including flag information indicating a match and index information indicating the entry of the buffer in which the mismatch character string determined to be a match is stored, in the nonvolatile memory; and storing the identified mismatch character string which does not match any of the mismatch character strings in the buffer in the buffer, and storing, as to the identified mismatch character strings, data based on a second data set including flag information indicating the mismatch and the identified mismatch character strings, in the nonvolatile memory.

Hereinafter, embodiments will be described with reference to the accompanying drawings.

### First Embodiment

First, the first embodiment will be explained.

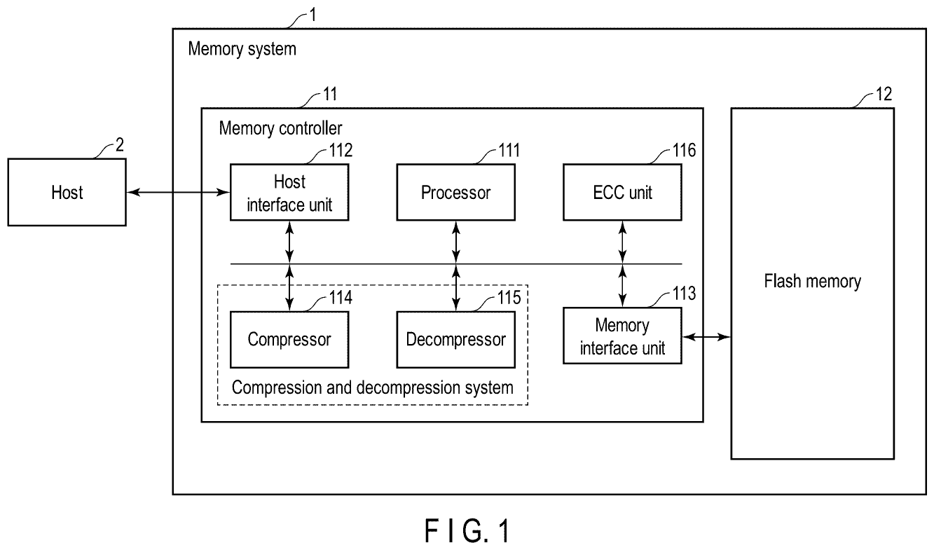

FIG. 1 is a diagram showing an example of a configuration of a memory system 1 of the first embodiment. FIG. 1 also shows an example of a configuration of an information processing system including the memory system 1 and a host 2 to which the memory system 1 is connected as storage. The host 2 is an information processing device such as a server or a personal computer.

The memory system 1 includes a memory controller 11 and a flash memory 12. Here, an example is shown in which the memory system 1 is realized as an SSD. The memory system 1 is not limited to SSDs, but can be realized as various types of data storage devices. In other words, the memory system 1 is not limited to a flash memory 12, but can be equipped with various types of storage media.

The memory controller 11 is a device which controls an overall operation of the memory system 1. The memory controller 11 includes a processor 111, a host interface unit 112, a memory interface unit 113, a compressor 114, a decompressor 115, and an error check and correction (ECC) unit 116.

The processor 111 executes a program called firmware or the like to realize various processes to be executed by the memory controller 11. The various processes to be executed by the memory controller 11 include a write process to write data to the flash memory 12 in response to write commands from the host 2 and a read process to read data stored in the flash memory 12 in response to read commands from the host 2. Although this description shows an example in which the various processes to be performed by the memory controller 11 are realized by the processor 111 executing firmware, they may also be realized by dedicated hardware, such as electrical circuits, built into the memory controller 11.

The host interface unit 112 controls communication with the host 2 in accordance with the predetermined communication standards. The memory interface unit 113 controls writing data to and reading data from the flash memory 12.

The compressor 114 compresses the write data requested to be written to the flash memory 12 by a write command to generate compressed data. The decompressor 115 decompresses the compressed data corresponding to the read data that was requested to be read from the flash memory 12 by a read command to obtain the read data. In other words, the memory system 1 of the first embodiment has a compression and decompression system that compresses and decompresses data.

The ECC unit 116 performs error correction processing on the compressed data generated by the compressor 114 and the entropy coding unit which is not shown. Specifically, upon receipt of a write command, the ECC unit 116 generates an error correction code to detect and correct errors in the compressed data to be written to the flash memory 12 in case errors occur in the future. The processor 111 is then configured to write the error correction code to the flash memory 12 via the memory interface unit 113. In other words, the processor 111 is configured to write data based on the compressed data generated by the compressor 114 and the entropy coding unit, which is not shown, to the flash memory 12 via the memory interface unit 113. When receiving a read command from the host 2, the processor 111 reads data based on the received read command from the flash memory 12 via the memory interface unit 113. The ECC unit 116 performs error correction processing on the read data. In other words, the ECC unit 116 checks for errors in the compressed data read from the flash memory 12 using error correction codes, and corrects the errors if any are detected. The read data for which error correction processing has been performed is input to the decompressor 115 by the processor 111 as compressed data, and the decompressor 115 decompresses the input compressed data. The processor 111 sends the decompressed data to the host 2 in response to a read command from the host 2. In other words, in response to a read command from the host 2, the processor 111 is configured to decompress data based on data read from the flash memory 12 and transmit the decompressed data to the host 2.

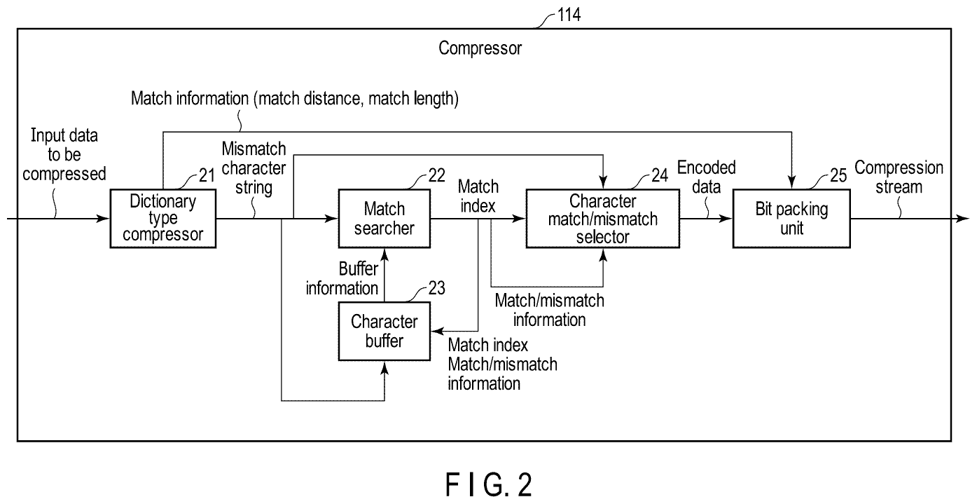

FIG. 2 is a diagram showing an example of a configuration of the compressor 114 of the memory system 1 of the first embodiment.

The compressor 114 of the first embodiment includes a dictionary type compressor 21, a match searcher 22, a character buffer 23, a character match/mismatch selector 24, and bit a packing unit 25.

The dictionary type compressor 21 stores previously input character strings as dictionary data in a buffer not shown in the figure, and searches for dictionary data which matches the input character strings in the dictionary data stored in the buffer. Here, the input strings will also be referred to as input data to be compressed. If there is a character string identical to the input character string as dictionary data, the dictionary type compressor 21 outputs information indicating the match, the match length, and the match distance. On the other hand, if the input string is not in the dictionary, the compressor 21 outputs information indicating that there was a mismatch and the mismatch character string of dictionary type compression. Here, the mismatch character string of dictionary type compression refers to the mismatch character string output from the dictionary type compressor 21, which is the string input to the dictionary type compressor 21. A typical algorithm is, for example, LZSS, an improved version of LZ77.

The match searcher 22 determines whether or not a character string which matches the mismatched character string of the dictionary type compression exists in the character buffer 23, based on the input mismatched character string of the dictionary type compression and the buffer information about the character string stored in the character buffer 23. If it exists, the match searcher 22 outputs information (match/mismatch information) indicating the match and the index (match idx) assigned to the matched string in the character buffer 23. If not exist, the match searcher 22 outputs information (match/mismatch information) indicating that there was a mismatch.

The character buffer 23 stores the mismatch character strings of dictionary type compression from 1 to (minimum match length of dictionary type compression −1) characters that have appeared in the past, and assigns an index to each string. More specifically, each entry in the character buffer 23, where character strings are stored one by one, is assigned an index. Basically, a smaller value of index is assigned to a newly entered string. The character buffer 23 outputs the character string with the assigned index as buffer information to the match searcher 22.

The character buffer 23 receives from the match searcher 22 the match/mismatch information of the mismatch character string in the dictionary type compression and, in case of a match, the index of the string, that is, the index of the entry in which the string is stored. If the match/mismatch information indicates a match, the character buffer 23 is updated so that the string stored in the entries from index “0” to (index −1 received from match searcher 22) shifts to (index +1), and the character string stored in the entry at (index received from the match searcher 22) is moved to the entry at index “0”. In the case of a mismatch, the character buffer 23 increments (+1) the indices of all strings in character buffer 23. In other words, all strings are shifted to the entry with (index+1). If the character buffer 23 is full, the strings stored in the entry with the (highest index value) are discarded. After all strings have been shifted, the character buffer 23 stores the most recently encountered dictionary type compression mismatch character string in the entry with index “0”.

The character match/mismatch selector 24 receives the match/mismatch information and the match index from the match searcher 22, and the mismatched character string of the dictionary type compression from the dictionary type compressor 21. If the match/mismatch information received from the match searcher 22 indicates a match, the character match/mismatch selector 24 outputs, as encoded data, a data set which includes information indicating that the match was a mismatch in the dictionary type compressor 21, information indicating that the match was a match in the character buffer 23, and the matching index in the character buffer 23. If the match/mismatch information received from the match searcher 22 indicates a mismatch, the character match/mismatch selector 24 outputs, as encoded data, a data set which includes information indicating that the match was a mismatch in the dictionary type compressor 21, information indicating that the match was also a mismatch in the character buffer 23, the number of characters in the mismatched character string in the dictionary type compression, the mismatched character string in the dictionary type compression.

The bit-packing unit 25 receives the match information from the dictionary type compressor 21 and the encoded data from the character match/mismatch selector, performs bit-packing as a compressed stream, and outputs it to the outside.

Here is an example where the compressor 114 performs dictionary type compression. Generally, a compression technique combining dictionary type compression and entropy coding is incorporated. The compressed stream output from the compressor 114 is entropy coded by the entropy coding unit not shown in FIG. 1 and output as compressed data. The ECC unit 116 receives the compressed data output from the entropy coding unit.

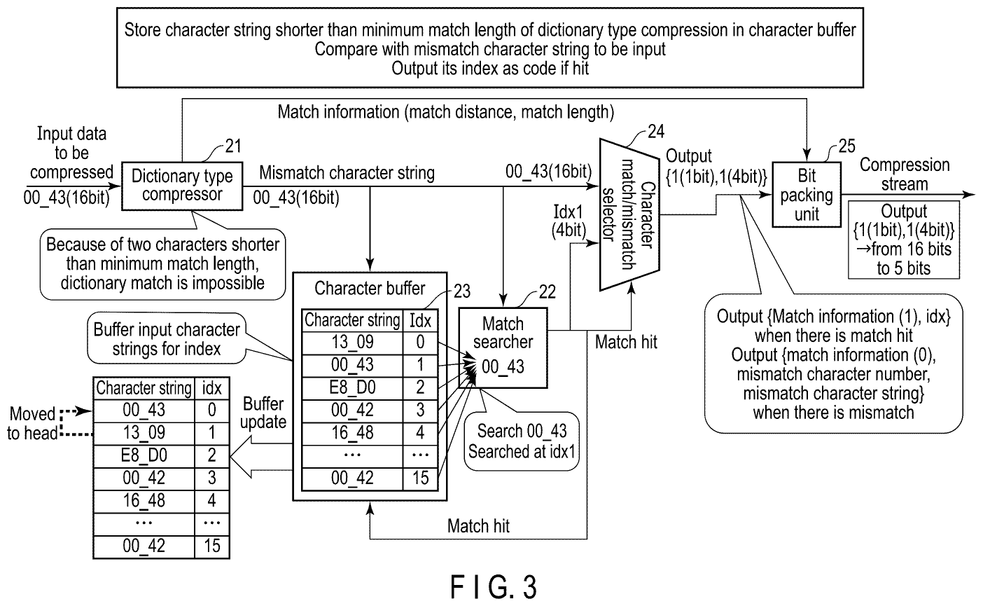

Referring now to FIG. 3, an overview of an operation of the compressor 114 of the memory system 1 of the first embodiment with the above configuration will be described.

The compressor 114 buffers the mismatch character strings of dictionary type compression with a predetermined length and outputs the index of the input dictionary type compression mismatch character string if it matches one of the strings in the buffer, thereby improving compression efficiency.

First, the operation when a character string that matches a mismatch character string in dictionary type compression is searched for in the buffer will be explained. For example, “13_09” (index “0”), “00_43” (index “1”), “E8_D0” (index “2”), . . . , “00_42” (index “15”) shall be stored. Suppose that the input string “00_43” is input to the dictionary type compressor 21 and output as a mismatch character string of dictionary type compression. For example, the minimum length of the match in dictionary compression is 3 or more characters. The mismatch character string of dictionary compression is input to the match searcher 22, which searches for “00_43” in the character buffer 23. In this example, there is a match, so the match searcher 22 outputs its index “1” and information indicating a match to character match/mismatch selector 24.

Because it matches the character string in the character buffer 23, the character match/mismatch selector 24 outputs the information indicating the match and its index information to the bit-packing unit 25. The bit-packing unit 25 packs the input data as a compressed stream and outputs it. On the other hand, the character buffer 23 is updated to bring the matched character string to the top because a character string matching the mismatched character string in the dictionary type compression was searched for. In this update, index “0” is “00_43”, index “1” is “13_09”, index “2” is “E8_D0”, . . . , and index “15” is “00_42”. In this manner, the indexes of values smaller than the index of the matched string “00_43” are incremented (+1), and the index of the matched string “00_43” becomes “0”.

Next, the operation when a character string that matches the mismatched character string in the dictionary type compression cannot be searched for in the buffer will be explained. For example, when “00_00” is input, the match searcher 22 outputs the mismatch information; when the mismatch information is received, the character match/mismatch selector 24 selects the mismatched character string “00_00”, information indicating that it was a mismatch, and the number of mismatched characters, and outputs it to the bit-packing unit 25. The bit-packing unit 25 packs the input data as a compressed stream and outputs it. On the other hand, the character buffer 23 sets “00_00”, which is input with the mismatch information, as index “0” and increments (+1) the indices of other character strings. The character string at index “15” is discarded.

Thus, the compressor 114 can compress mismatch character strings of dictionary type compression when the mismatch character string is shorter than the minimum match length of dictionary type compression, thus improving compression efficiency.

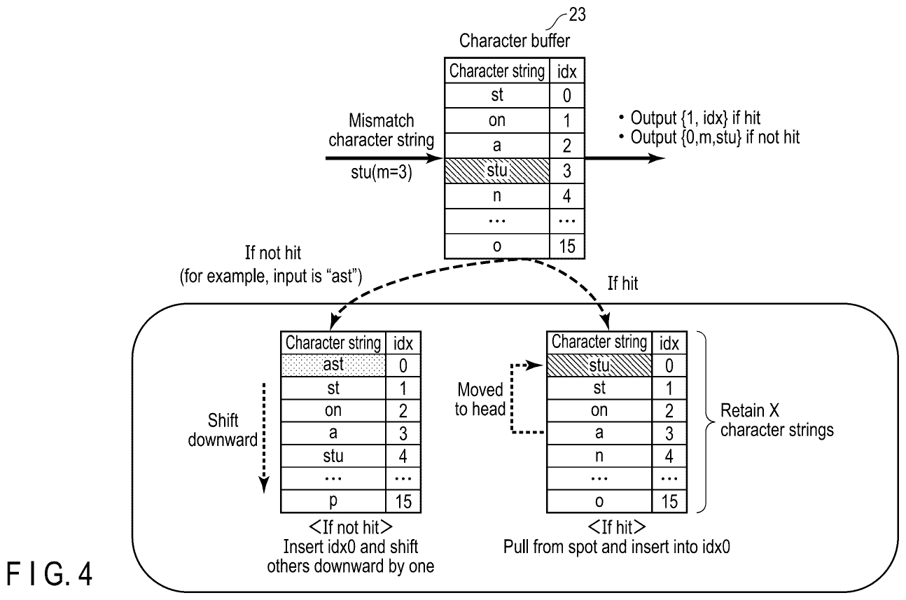

Referring to FIG. 4, the outline of the operation of the compressor 114, including updating of the character buffer 23, will be further explained with specific examples such as character strings in the character buffer 23.

If a mismatch character string in the dictionary type compression exists in the character buffer 23, that is, if it is a hit, the match searcher 22 outputs a data set containing information indicating that it is a hit (match/mismatch information) 1 bit “1” and its index.

On the other hand, if the mismatch character string of the dictionary compression does not exist in the character buffer 23, that is, if there is no hit, the match searcher 22 outputs a data set including 1 bit “0” indicating that there was no hit (match/mismatch information), the number of characters (m: m is one of the numbers from 1 to (minimum match length of dictionary compression −1)), and the mismatch character string of the dictionary compression.

Assuming that “stu” is input from the dictionary type compressor 21 as a mismatch character string for dictionary compression, “stu” is a hit because it exists in the character buffer 23. The match searcher 22 outputs a data set including the match/mismatch information “1” indicating a match and the index “3”. In this case, the character buffer 23 removes the hit string “stu” from index “3” and puts it at the top index “0”. The hit string “stu” is moved to the first index “0”. The indexes “0” to “2” before moving “stu” are incremented (+1), respectively.

Next, assume that “ast”, which does not exist in the character buffer 23, is input as a mismatch character string of dictionary compression. Since it does not exist in the character buffer 23 and is not a hit, the match searcher 22 outputs a data set containing the match/mismatch information “0” indicating a mismatch, the number of characters “3”, and the mismatched character string of the dictionary compression “ast”. In this case, the character buffer 23 stores it in the first index “0” and increments (+1) the indices of the other character strings. In other words, the other strings are shifted down by one.

The above is the overview of the operation of the compressor 114 in the memory system of the first embodiment. When a string shorter than the minimum match length is output from the dictionary type compressor 21 as a mismatch character string of dictionary compression, the compressor 114 can compress and encode the mismatch character string of dictionary compression into a few bits of data set including mismatch information and an index, if the mismatch character string exists in the character buffer 23. Therefore, the compressor 114 of the first embodiment can improve compression efficiency.

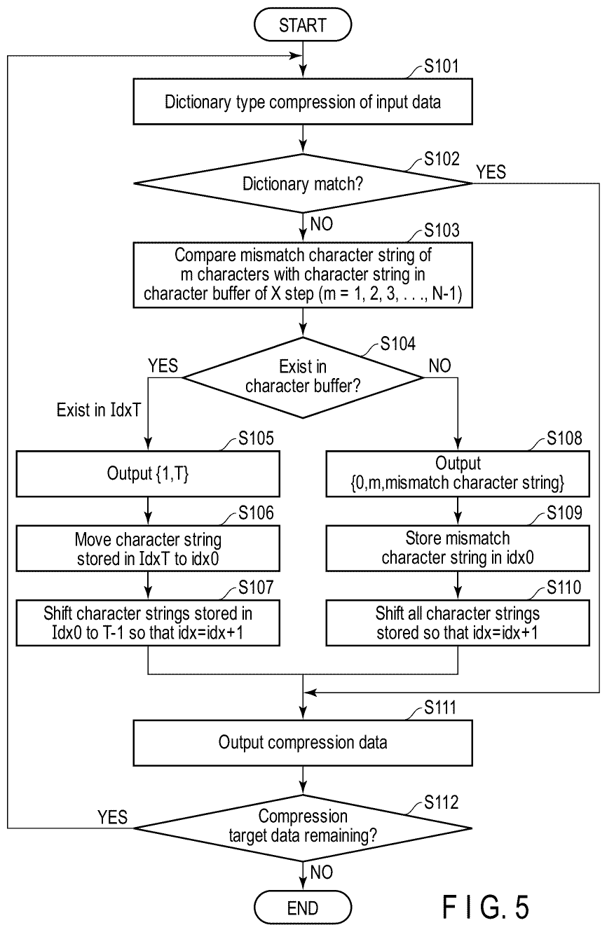

FIG. 5 is a flowchart showing an operating procedure of the compressor 114 of the memory system of the first embodiment.

The dictionary type compressor 21 performs dictionary compression of the input data (S101). If the dictionary is matched (S102: YES), the bit-packing unit 25 outputs the information output from the dictionary type compressor 21 as compressed data (S111).

If there is no dictionary match (S102: NO), the match searcher 22 compares m mismatch character strings of dictionary compression with the strings in the character buffer 23 at X (X is a natural number greater than or equal to 1) tiers (S103). If the mismatch character string of dictionary type compression exists in the character buffer 23 (S104: YES), the match searcher 22 outputs a data set including the match/mismatch information “1” indicating a match and the index “T” (T is one of the numbers from 0 to X−1) of the entry where the string matching the mismatch character string of dictionary type compression is stored (S105).

The character buffer 23 moves the character string stored in the entry with index “T” to the entry with index “0” (S106). At that time, the character buffer 23 shifts the character string stored in the entry with index “0” to the entry with index “T−1” so that the index becomes+1 (S107).

If the mismatch character string of the dictionary compression does not exist in the character buffer 23 (S104: NO), the match searcher 22 outputs a data set that includes the match/mismatch information “0” indicating a mismatch, the number of characters “m”, and the mismatch character string of the dictionary compression (S108).

The character buffer 23 stores the mismatch character strings of the dictionary type compression at index “0” (S109). At that time, the character buffer 23 shifts all stored strings so that the index becomes +1 (S110).

If there is no dictionary match, the bit packing unit 25 outputs the information output from the match searcher 22 as compressed data (S111).

The compressor 114 determines whether or not data to be compressed remains (S112), and if so (S112: YES), returns to S101 and executes a series of processes from dictionary type compression of input data by the dictionary type compressor 21. If there is no remaining (S112: NO), the compressor 114 terminates the compression process.

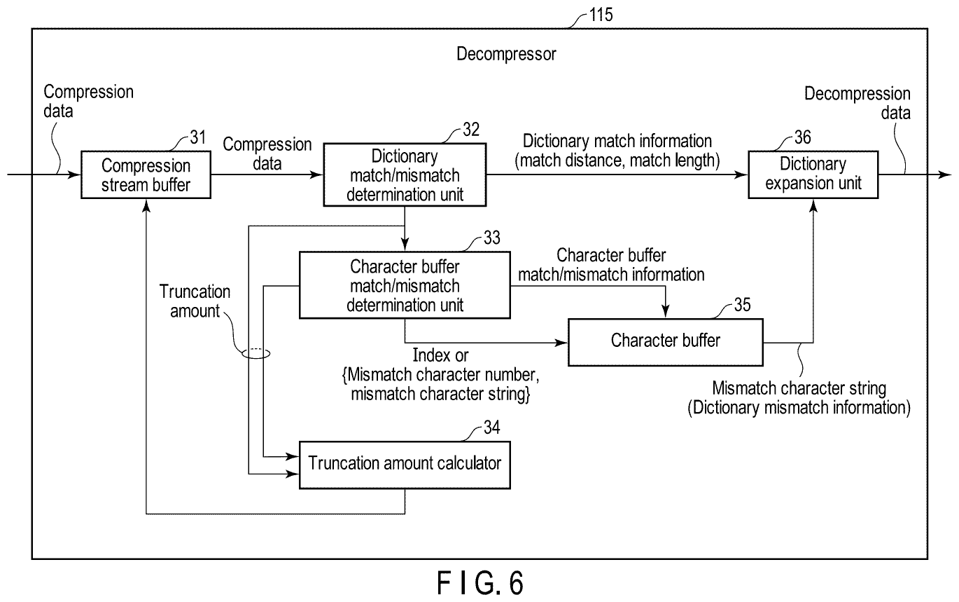

Next, details of the decompressor 115 in the first embodiment will be explained. FIG. 6 is a diagram showing an example of a configuration of the decompressor 115 of the first embodiment.

The decompressor 115 of the first embodiment includes a compressed stream buffer 31, a dictionary match/mismatch determination unit 32, a character buffer match/mismatch determination unit 33, a truncation amount calculation unit 34, a character buffer 35, and a dictionary type decompression unit 36.

The compressed stream buffer 31 is a buffer which takes in and stores compressed streams from the outside. When the compressed stream buffer 31 receives a truncation amount from the truncation amount calculation unit 34, it truncates the compressed stream from the beginning by the truncation amount.

The dictionary match/mismatch determination unit 32 acquires the compressed data stored in the compressed stream buffer 31 and first reads the first 1 bit. If the value of the first bit is “1”, the following data is the dictionary match information. The dictionary match/mismatch determination unit 32 then reads Y bits as the dictionary agreement information, where Y is the number of bits indicating the match length and the match distance in dictionary type compression. The match length indicates the number of characters in the matched string. The match distance indicates the starting position of the matched string in the dictionary. The dictionary match/mismatch determination unit 32 outputs the dictionary match information to the dictionary type decompression unit 36.

On the other hand, if the value of the first 1 bit is “0”, the following data is the dictionary mismatch information. The dictionary mismatch information is information including (i) the index of the entry in the character buffer 35 where the character string which matches the mismatched character string of the dictionary compression is stored, or (ii) the number of characters in the mismatched character string of the dictionary compression and the mismatched character string of the dictionary compression. The dictionary match/mismatch determination unit 32 outputs the dictionary mismatch information to the character buffer match/mismatch determination unit 33.

When the value of the first 1 bit is “1”, that is, the dictionary is matched, the dictionary match/mismatch determination unit 32 outputs “1+Y” to the cutout calculation unit 34. On the other hand, if the value of the first 1 bit is “0”, that is, if the dictionary mismatch occurred, the dictionary match/mismatch determination unit 32 outputs “1” to the truncation amount calculation unit 34.

The character buffer match/mismatch determination unit 33 first reads the first 1 bit of the dictionary mismatch information received from the dictionary mismatch determination unit 32. This 1 bit is the character buffer match/mismatch information. If it is “1”, the mismatched character string of the dictionary type compression matches one of the character strings in the character buffer 35. In this case, the character buffer match/mismatch determination unit 33 then reads the [log 2 (X)] bit, where X is the depth (number of tiers) of the character buffer 35.

[The [log 2 (X)] surrounded by [ ] is a ceiling function which rounds up the decimal point of log 2 (X), and the [log 2 (X)] bit is the number of bits required to express X numbers from 0 to X−1 in binary. The value of the [log 2 (X)] bit is the index of the entry in the character buffer 35 which stores the string that matches the mismatch character string of the dictionary type compression in the X entries.

On the other hand, if the character buffer match/mismatch information is “0”, the mismatched character string of dictionary type compression is a character string which is not in the character buffer 35. In this case, the character buffer match/mismatch determination unit 33 then reads the [log 2 (N−1)] bit, where N is the minimum match length of the dictionary type compression. The [log 2 (N−1)] is also a ceiling function, and the [log 2 (N−1)] bit is the number of bits required to represent N−1 numbers from 1 to N−1 in binary. The value of the [log 2 (N−1)] bit is the number of characters of the mismatched character string of dictionary type compression. The character buffer match/mismatch determination unit 33 sets the value of [log 2 (N−1)] bits, that is, the number of characters of the mismatch character string of dictionary type compression, to m, and then reads m*8 bits. The value of m*8 bits is the mismatch character string of dictionary type compression.

The character buffer match/mismatch determination unit 33 outputs the character buffer match/mismatch information (“1” or “0”), and the acquired data (index, or character count and dictionary type compression mismatch character string) to the character buffer 35.

When the character buffer match/mismatch information is “1”, the character buffer match/mismatch determination unit 33 outputs 1+[log 2 (X)] to the truncation amount calculation unit 34. On the other hand, if the character buffer match/mismatch information is “0”, the character buffer match/mismatch determination unit 33 outputs 1+[log 2 (N−1)]+m*8 to the truncation amount calculation unit 34.

The truncation amount calculation unit 34 adds the value received from the dictionary match/mismatch determination unit 32 and the value received from the character buffer match/mismatch determination unit 33, and outputs it as the truncation amount to the compressed stream buffer 31.

The Character buffer 35 receives character buffer match/mismatch information from character buffer match/mismatch determination unit 33. If the received character buffer match/mismatch information is “1”, the other data received from the character buffer match/mismatch determination unit 33 is the index of the entry in the character buffer 35. In this case, the character buffer 35 reads the character string stored in the entry at that index and outputs it to the dictionary type decompression unit 36 as a mismatched character string of dictionary type compression.

The character buffer 35 moves the character string stored in the entry with index “T” received from the character buffer match/mismatch determination unit 33 to the entry with index “0”. T is an integer greater than or equal to 1. In this case, the character buffer 35 shifts the character string stored in the entries from index “0” to index “T−1” so that the index becomes +1.

On the other hand, if the character buffer match/mismatch information is “0”, the other data received from the character buffer match/mismatch determination unit 33 is a character buffer mismatch character string (character number and mismatch character string of character count and dictionary type compression). In this case, the character buffer 35 outputs the mismatch character string of dictionary type compression to dictionary type decompression unit 36.

The character buffer 35 also stores the character buffer mismatch character string in the entry with index “0”. At that time, the character buffer 35 shifts all other character strings so that the index becomes +1.

In other words, the character buffer 35 of the decompressor 115 stores mismatch character strings of dictionary type compression or moves strings within the character buffer 23 of the compressor 114 so as to reproduce the fact that the character buffer 23 of the compressor 114 stores mismatch character strings of dictionary type compression or moves strings within the character buffer 23.

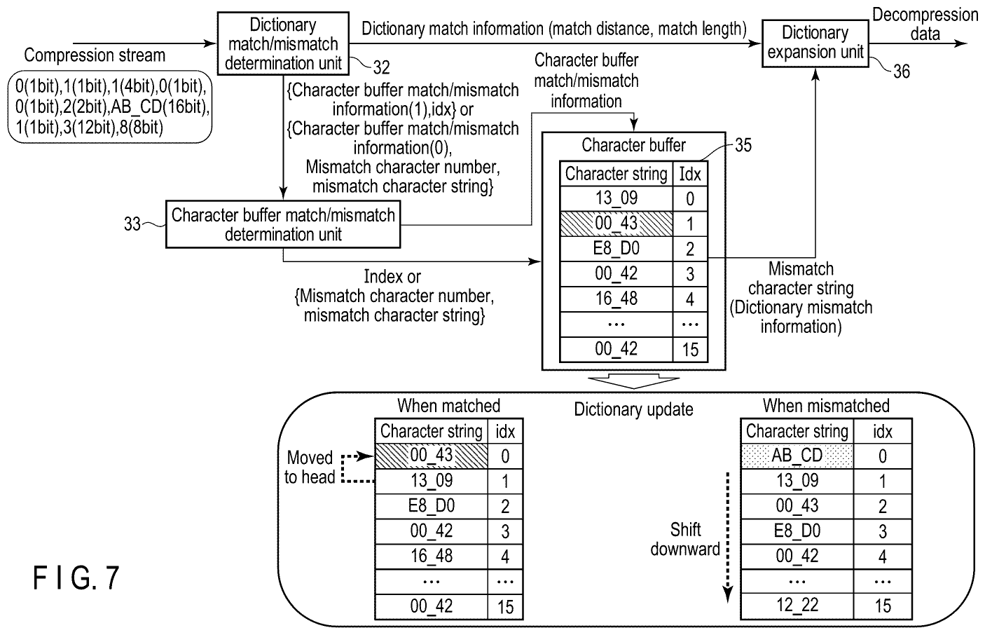

Referring to FIG. 7, an overview of the operation of the decompressor 115 in the memory system of the first embodiment with the above configuration, including updating of the character buffer 35, will be described with specific examples of compressed streams and character strings in the character buffer 35.

Here, a case where “0 (1 bit), 1 (1 bit), 1 (4 bit), 0 (1 bit), 0 (1 bit), 2 (2 bit), AB_CD (16 bit), 1 (1 bit), 3 (12 bit), 8 (8 bit)” are input as compressed streams will be considered.

The dictionary match/mismatch determination unit 32 first reads the first 1 bit. Since the first 1 bit is “0”, it is known to be the dictionary mismatch information. Therefore, the next 1 bit is the match/mismatch information in the character buffer 35.

The character buffer match/mismatch determination unit 33 reads this match/mismatch information. Since the match/mismatch information is “1”, it can be known that the index follows next. Here, it is assumed that the value of the index is expressed in 4 bits, based on the depth (number of tiers) of the character buffer 35. The character buffer match/mismatch determination unit 33 reads the 4 bits and obtains “1”.

The character buffer 35 reads the character string stored in the entry with index “1” and outputs it to the dictionary decompression unit 36 as a mismatched character string of dictionary compression. The character buffer 35 moves the character string stored in the entry with index “1” to the entry with index “0” and shifts the character string stored in the entry with index smaller value than “1”, that is, index “0” so that the index becomes +1.

Next, the dictionary match/mismatch determination unit 32 reads the next first bit. Since this first bit is also “0”, it is known to be dictionary mismatch information. Therefore, the next first bit is the match/mismatch information of the character buffer 35.

The character buffer match/mismatch determination unit 33 reads this match/mismatch information. Since the match/mismatch information is “0”, it can be known that the number of mismatched characters and the mismatched character string of the dictionary type compression follow next. The character buffer match/mismatch determination unit 33 reads the number of mismatched characters m*8 bits and obtains the character string “AB_CD”.

The character buffer 35 outputs the character string “AB_CD” received from the character buffer match/mismatch determination unit 33 to the dictionary type decompression unit 36. The character buffer 35 stores the string “AB_CD” in the entry with index “0” and shifts all other character strings so that the index becomes +1.

Finally, the dictionary match/mismatch determination unit 32 reads the next first bit. Since this first bit is “1”, it can be known that this is the dictionary match information. Therefore, it can be known that the match distance and match length follow next. The number of bits of the matching distance and the number of bits of the matching length may vary depending on the configuration of the dictionary type compressor 21 in the compressor 114 and the dictionary type decompression unit 36 in the decompressor 115, but here assumed is that they are 12 bits and 8 bits. The dictionary match/mismatch determination unit 32 reads the 12 bits and 8 bits, obtains the match distance “3” and the match length “8”, and outputs them to the dictionary type decompression unit 36.

Suppose that, when the character buffer 35 is in the state shown in FIG. 7, “00_43” stored in the entry with index “1” in the character buffer 35 is sent to the character buffer 35 as a mismatch character string for dictionary type compression. In this case, the character buffer 35 moves “00_43” to the entry with index “0” and shifts “13_09” stored in the entry with index smaller value than “1”, that is, index “0” so that the index becomes +1 (index “1”).

If “AB_CD” which is not in the character buffer 35 is sent to the character buffer 35 as a mismatch character string of the dictionary type compression, the character buffer 35 stores “AB_CD” in the entry of index “0” and all other strings are shifted so that the index becomes +1.

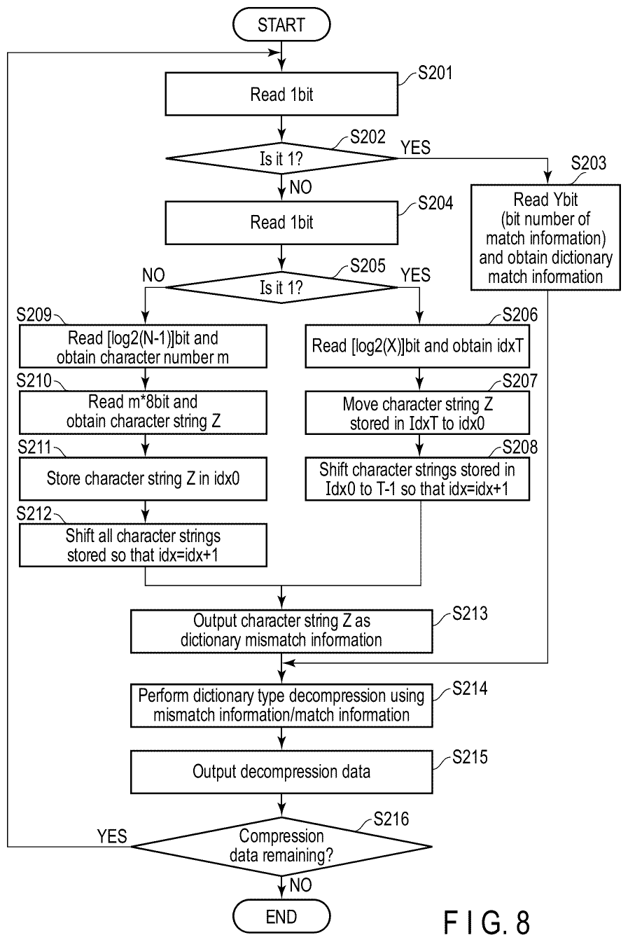

FIG. 8 is a flowchart showing an operating procedure of the decompressor 115 of the memory system of the first embodiment.

The dictionary match/mismatch determination unit 32 reads the first 1 bit of the compressed data stored in the compressed stream buffer 31 (S201). If the first bit is “1” (S202: YES), the following data is a dictionary match string. The dictionary match/mismatch determination unit 32 then reads the number of bits (Ybit) of data for the match information and outputs it to the dictionary type decompression unit 36 as dictionary match information (S203).

On the other hand, if the first 1 bit of compressed data is “0” (S202: NO), the following data is a mismatch character string of dictionary type compression. The character buffer match/mismatch determination unit 33 reads the next 1 bit (S204). If “1” (S205: YES), the mismatch character string of dictionary type compression matches one of the character strings in the character buffer 35. The character buffer match/mismatch determination unit 33 then reads the [log 2 (X)] bit (S206), where X is the depth (number of tiers) of the character buffer 35 and the value “T” of the [log 2 (X)] bit is the index of the character buffer 35. The character string Z stored in the entry with index “T” is the character string which matches the mismatched character string of the dictionary type compression.

The character buffer 35 moves the character string Z stored in the entry with index “T” to the entry with index “0” (S207). At that time, the character buffer 35 shifts the character string stored in the entry with index “0” to the entry with index “T−1” so that the index becomes +1 (S208).

The character buffer 35 outputs the character string stored in the entry with index “T” to the dictionary type decompression unit 36 as dictionary mismatch information (S213).

If the next first bit is “0” (S205: NO), the mismatch character string of dictionary type compression is a string that is not in the character buffer 35. The character buffer match/mismatch determination unit 33 then reads the [log 2 (N−1)] bits (S209). The value “m” of the [log 2 (N−1)] bit is the number of characters of the mismatched character string of the dictionary type compression. The character buffer match/mismatch determination unit 33 further reads m*8 bits. The value of m*8 bits is the mismatched character string (character string Z) of the dictionary type compression (S210).

The character buffer 35 stores the character string Z obtained by the character buffer match/mismatch determination unit 33 in the entry with index “0” (S211). At that time, the character buffer 35 shifts all character strings stored in the character buffer 35 so that the index becomes +1 (S212).

The character buffer 35 outputs character string Z to the dictionary type decompression unit 36 as dictionary mismatch information (S213).

The dictionary type decompression unit 36 performs dictionary type decompression based on the dictionary match information received from the dictionary mismatch determination unit 32 or the dictionary mismatch information received from the character buffer 35 (S214), and outputs the decompressed data (S215).

The decompressor 115 determines whether or not compressed data remains (S216), and if so (S216: YES), returns to S201 and executes a series of processes starting from reading the first bit by the dictionary match/mismatch determination unit 32. If there is no remaining (S216: NO), the decompressor 115 terminates the decompression process.

As described above, in the memory system 1 of the first embodiment, the compressor 114 buffers the mismatch character strings of dictionary type compression with a certain length, and if the input mismatch character string of dictionary type compression matches one of its character buffers, it outputs its index, thereby improving the efficiency of compression.

For example, the memory system 1 of the first embodiment can improve compression efficiency even when the minimum match length for dictionary type compression is 3 Bytes, and when data in which certain 2-byte data appear frequently is input.

In other words, the compressor 114 of the memory system 1 of the first embodiment allows compression of strings shorter than the minimum match length for dictionary type compression.

### Second Embodiment

Next, the second embodiment is described. Like the first embodiment, the second embodiment is also shown as an example of a memory system realized as an SSD. The same reference numbers are used for the same components as in the first embodiment, and their descriptions will be omitted.

In the first embodiment, the character buffer 23 of the compressor 114 and the character buffer 35 of the decompressor 115 store a string of m characters. Here, m is one of the numbers from 1 to (minimum match length−1). In contrast, in the second embodiment, the character buffer 23 of the compressor 114 and the character buffer 35 of the decompressor 115 store only M characters, which is a predefined fixed value, for example, (minimum match length−1).

In the first embodiment, the compressor 114 outputs a data set that includes the match/mismatch information indicating the mismatch, the number of characters, and the mismatch character string of dictionary type compression, if the mismatch character string of dictionary type compression does not exist in the character buffer 23. In contrast, in the second embodiment, the compressor 114 is not required to include the number of characters in the data set to be output when the mismatch character string of dictionary type compression does not exist in the character buffer 23.

This makes the compressor 114 of the second embodiment more efficient in compression.

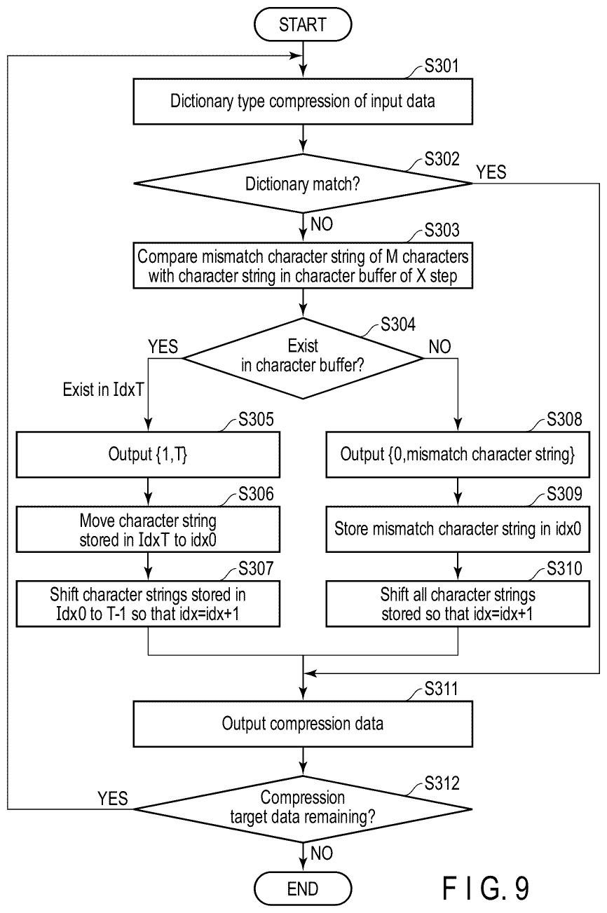

FIG. 9 is a flowchart showing an operating procedure of the compressor 114 of the memory system 1 of the second embodiment. Here, only the parts (S303 and S308) that differ from the first embodiment (FIG. 5) will be explained.

The match searcher 22 compares the mismatch character string of the dictionary type compression of M characters with the string in the X-tiers character buffer (S303), where M is a fixed value.

If the mismatch character string of the dictionary compression does not exist in the character buffer 23, the match searcher 22 outputs a data set which includes the match/mismatch information “0” indicating a mismatch and the mismatch character string of the dictionary compression (S308). This data set does not include the number of characters.

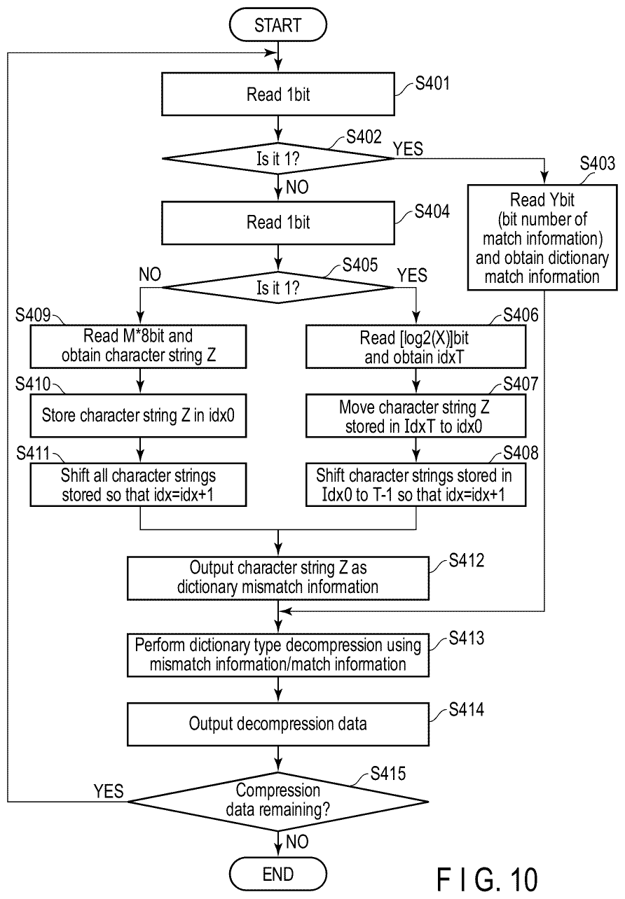

FIG. 10 is a flowchart showing an operating procedure of the decompressor 115 of the memory system 1 of the second embodiment. Here, only the part (S409) that differs from the first embodiment (FIG. 8) will be explained.

If the first 1 bit of the compressed data is “0” and the next first 1 bit is also “0”, the character buffer match/mismatch determination unit 33 reads M*8 bits and sets the value as character string Z (S409). In the first embodiment, it was necessary to read [log 2 (N−1)] bits to obtain the number of characters because the number of characters in the mismatch character string in the dictionary type compression is variable. In contrast, in the second embodiment, the number of characters in the mismatch character string of dictionary type compression is a fixed value of M, so there is no need to read the compressed data to obtain the number of characters.

In other words, the memory system 1 of the second embodiment can reduce the processing load of the decompressor 115.

As described above, the memory system 1 of the second embodiment can further improve the compression efficiency of the compressor 114 and can reduce the processing load of the decompressor 115, by limiting the number of characters of the character strings stored in the character buffer 23 of the compressor 114 and the character buffer 35 of the decompressor 115 to only M characters, a predefined fixed value, for example (minimum match length−1).

### Third Embodiment

Next, the third embodiment will be explained.

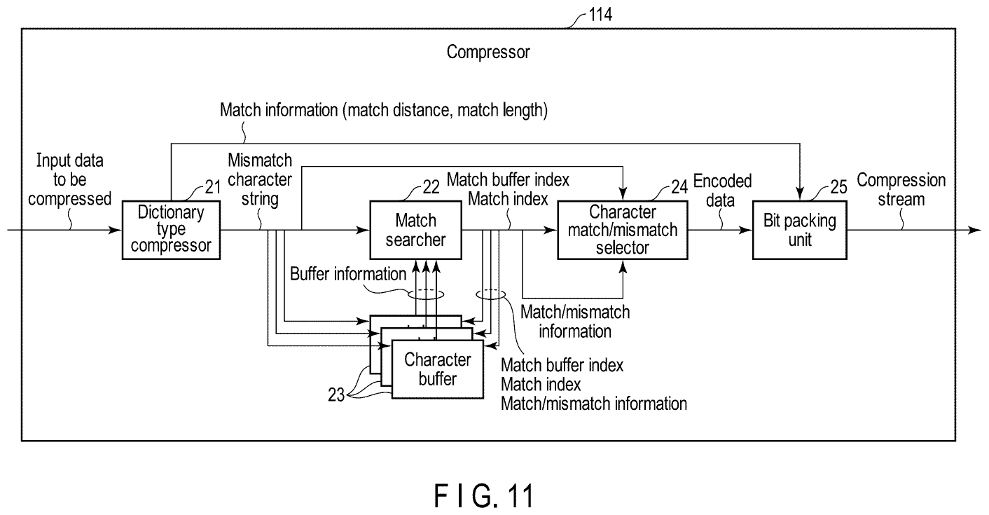

FIG. 11 is a diagram showing an example of a configuration of the compressor 114 in the memory system 1 of the third embodiment.

As shown in FIG. 11, the compressor 114 of the third embodiment has a character buffer 23 for each number of characters of the mismatch character string of dictionary type compression. Here, an example in which the minimum match length of the dictionary type compression is 4, and there are three character buffers 23 for the number of characters “1”, character buffer 23 for the number of characters “2”, and character buffer 23 for the number of characters “3” will be used.

The match searcher 22 of the third embodiment determines whether or not a character string which matches the mismatched character string of the dictionary type compression exists in any of the character buffers 23 based on the mismatched character string of the dictionary type compression from the dictionary type compressor 21 and the buffer information of the multiple character buffers 23. If it exists, the match searcher 22 outputs information indicating the match (match/mismatch information), index (buffer index) indicating one of the three character buffers 23, and index (string index) indicating the entry of the character buffer 23 which stores the character string that matches the mismatched character string of the dictionary type compression. If it does not exist, the match searcher 22 outputs information (match/mismatch information) indicating that it was a mismatch as in the first embodiment.

When information (match/mismatch information) indicating a match is output from the match searcher 22, the character buffer 23 in the third embodiment determines whether or not the buffer index output with the match/mismatch information indicates itself. If it indicates itself, the character buffer 23 acquires the character string index output with the match/mismatch information and updates the character buffer 23 based on this index, as described in the first embodiment. In other words, the character string stored in the entry with the obtained index is moved to index “0”, and the character string stored in the entries from index “0” to (obtained index −1) are shifted so that the index becomes (index +1).

When information (match/mismatch information) indicating a mismatch is output from the match searcher 22, the character buffer 23 determines whether or not the mismatch character string in the dictionary type compression is a string which should be store by itself, based on the number of characters in the mismatch character string in the dictionary type compression also output from match searcher 22. If it should be stored by itself, the character buffer 23 stores the string as described in the first embodiment. That is, the character buffer 23 stores the mismatch character string of the compressed dictionary type in the entry with index “0” and shifts all stored strings so that the index becomes index +1.

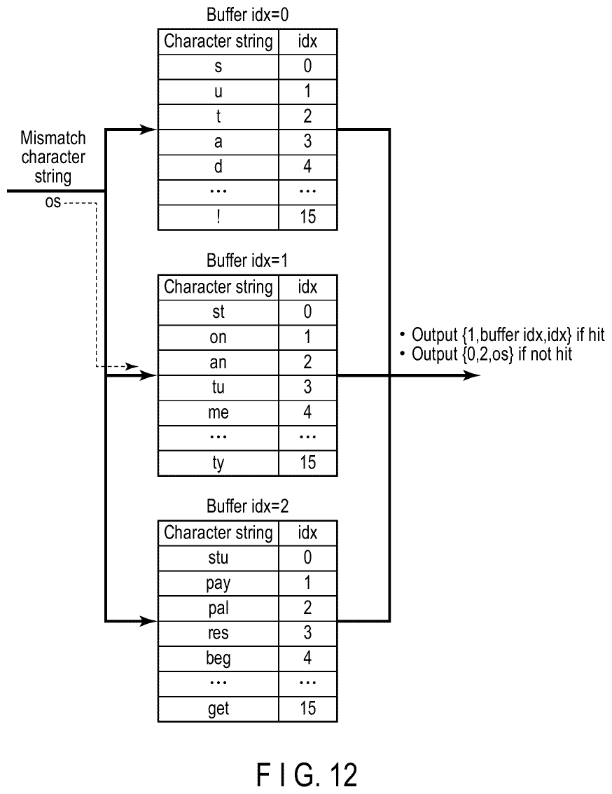

FIG. 12 is a diagram showing a concept of updating the character buffer 23 in the third embodiment.

In FIG. 12, the index of character buffer 23 which stores character string of length 1 is “0”, the index of character buffer 23 which stores the character string of length 2 is “1”, and the index of character buffer 23 which stores the character string of length 3 is “2”.

For example, if the mismatch character string in the input dictionary type compression is “os”, the match searcher 22 searches for the character buffer 23 with index “1”, which stores a string of character length 2. If the input string is in the character buffer 23 with index “1”, the match searcher 22 outputs information (match/mismatch information “1”) indicating that a match has occurred, information (buffer index “1”) indicating which character buffer 23 the string was matched with, and the index (string index) of the entry in that character buffer 23. In the case of a mismatch, the match searcher 22 outputs the information (match/mismatch information “0”) indicating that it was a mismatch, the number of characters, and the mismatched character string of the dictionary type compression, as in the first embodiment.

The character buffer 23 with index “1” which stores “os” is updated in the same way as the first embodiment. Note that the number of the tiers of the plurality of the character buffers 23 may not necessary be the same. For example, based on the statistics of the mismatch character strings of compressed dictionary types that have appeared, the number of tiers of the character buffer 23 with more appearance may be increased, and the number of tiers of the character buffer 23 with fewer appearance may be decreased.

In the third embodiment, character strings with more appearance are not driven out of the character buffer 23 by character strings with fewer appearance. In addition, since the number of tiers can be changed among the plurality of the character buffers 23, it is possible to store strings with more appearance in a character buffer 23 for a long period of time by increasing the number of tiers of the character buffer 23 which stores strings with more appearance over the number of tiers of the character buffer 23 which stores strings with fewer appearance. This allows the compressor 114 of the third embodiment to improve compression efficiency.

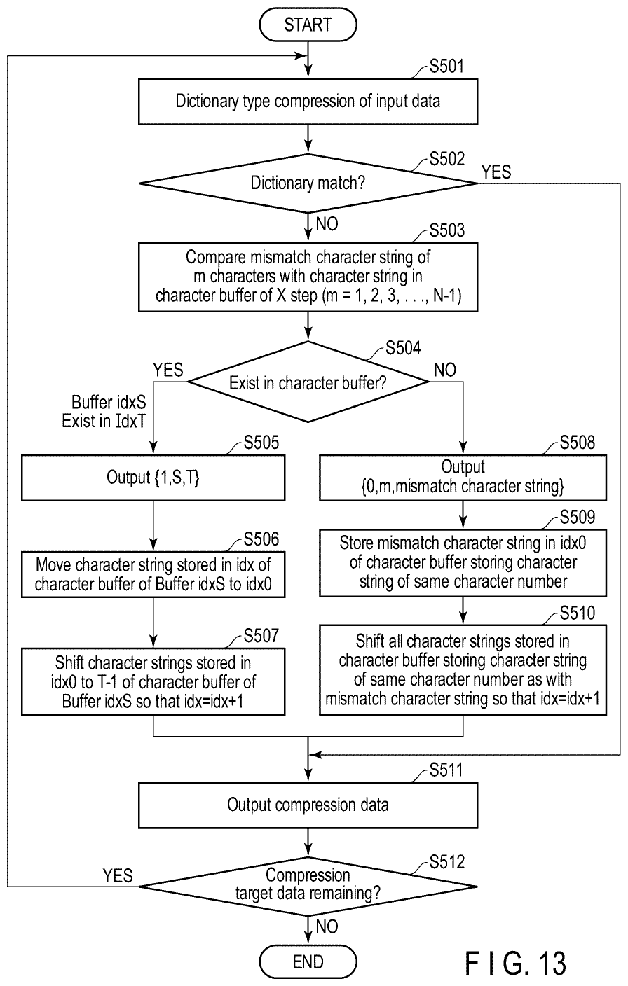

FIG. 13 is a flowchart showing an operating procedure of the compressor 114 in the memory system 1 of the third embodiment. Here, only the parts (S505, S506, S507, S509, and S510) which differ from the first embodiment (FIG. 5) will be explained.

When a mismatch character string of compressed dictionary type exists in the character buffer 23, the match searcher 22 outputs a data set including the match/mismatch information “1” indicating a match, buffer index “S” of the character buffer 23 where the string which matches the mismatch character string of compressed dictionary type is existed, and string index “T” of the entry of the character buffer 23 where the string which matches the mismatch character string of compressed dictionary type is stored (S505). In other words, the buffer index “S” is added to the data set compared to the first embodiment.

The character buffer 23 with buffer index “S” moves the character string stored in the entry with index “T” to the entry with index “0” (S506). At that time, the character buffer 23 with buffer index “S” shifts the character strings stored in the entry with index “0” to the entry with index “T−1” so that the index becomes +1 (S507). The character buffers 23 with buffer indexes other than “S” do nothing in S506 and S507.

If the mismatch character string of the dictionary compression does not exist in the character buffer 23, and the match searcher 22 outputs a data set including the match/mismatch information “0” indicating a mismatch, the number of characters “m”, and the mismatch character string of the dictionary compression, the mismatch character string of the dictionary compression is stored in the entry with index “0” in the character buffer 23 which stores the string with the same number of characters (S509). At that time, the character buffer 23, which stores the same number of characters as the mismatch character string of the dictionary compression, is shifted so that all stored strings have an index of +1 (S510).

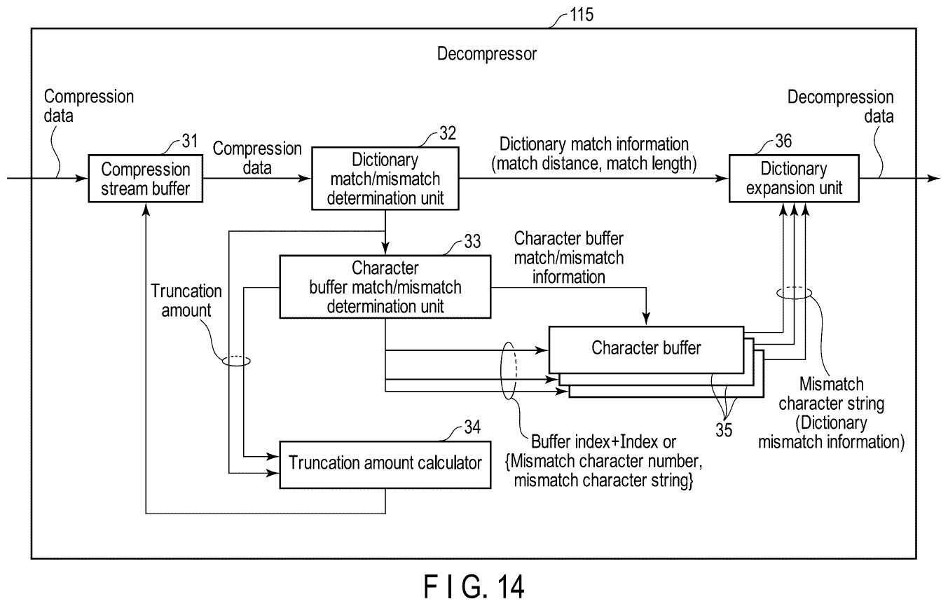

FIG. 14 is a diagram showing an example of a configuration of the decompressor 115 in the memory system 1 of the third embodiment.

As shown in FIG. 14, the decompressor 115 of the third embodiment, like the compressor 114, has a character buffer 35 for each character number of the mismatch character string of dictionary type compression. Specifically, it has three character buffers 35: character buffer 35 for the number of characters “1”, character buffer 35 for the number of characters “2”, and character buffer 35 for the number of characters “3”.

The character buffer match/mismatch determination unit 33 of the third embodiment reads the first 1 bit of the compressed data received from the dictionary match/mismatch determination unit 32. This 1 bit is the character buffer match/mismatch information.

If the character buffer match/mismatch information is “1”, the mismatched character string of the dictionary type compression matches one of the character strings in any of the 35 character buffers. In this case, the character buffer match/mismatch determination unit 33 then reads the [log 2 (L)] bit, where L is the number of character buffers. The [log 2 (L)] bit is also a ceiling function, and the [log 2 (L)] bit is the number of bits required to express, for example, L numbers from 0 to L−1 in binary. The value of the [log 2 (L)] bit is an index (buffer index) indicating one of the three character buffers 35. The character buffer match/mismatch determination unit 33 sets the value of the [log 2 (L)] bit, or buffer index, to S.

The character buffer match/mismatch determination unit 33 then reads the [log 2 (X_{S})] bit, where X_{S} is the depth (number of tiers) of the character buffer 35 indicated by the buffer index “S”. The [log 2 (X_{S})] bit is the number of bits required to represent X_{S} numbers in binary from 0 to X_{S}−1, for example. The value of the [log 2 (X_{S})] bit is the index of the entry in the character buffer 35 which stores the string that matches the mismatch character string of the dictionary type compression among the X entries in the buffer, indicated by the buffer index “S”.

If the character buffer match/mismatch information is “0”, the character buffer match/mismatch determination unit 33 then reads the [log 2 (N−1)] bits to obtain the number of characters (m) of the mismatched character string in the dictionary type compression. Furthermore, the character buffer match/mismatch determination unit 33 reads m*8 bits to obtain the mismatched character string of the dictionary compression.

The character buffer match/mismatch determination unit 33 outputs the character buffer match/mismatch information (“1” or “0”), and the acquired data (index, or character count and mismatch character string of dictionary type compression) to the three character buffers 35.

Each of the 35 character buffers receives character buffer match/mismatch information from the character buffer match/mismatch determination unit 33, respectively. When the received character buffer mismatch information is “1”, the other two data received from the character buffer match/mismatch determination unit 33 are the buffer index and the character string index. In this case, each character buffer 35 determines whether the buffer index indicates it or not. The character buffer 35 indicated by the buffer index reads the character string stored in the entry of the character string index and outputs it to the dictionary type decompression unit 36 as a mismatched character string of dictionary type compression.

The character buffer 35, indicated by the buffer index, shifts the character string stored in the entry with string index “T” to the entry with index “0”, and shifts the character string stored in the entries from index “0” to index “T−1” so that the index becomes +1.

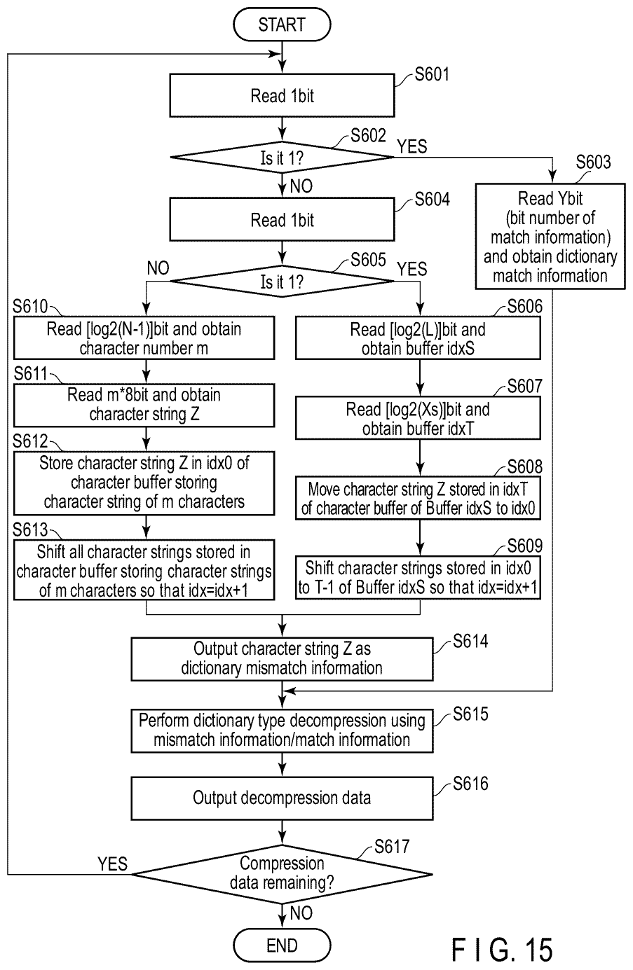

FIG. 15 is a flowchart showing an operating procedure of the decompressor 115 in the memory system 1 of the third embodiment. Here, only the parts (S606 to S609, S612, and S613) that differ from the first embodiment (FIG. 8) will be explained.

If the first bit of the compressed data is “0” and the next bit is “1”, the character buffer match/mismatch determination unit 33 then reads the [log 2 (L)] bit (S606). L is the number of character buffers 35, and the value “S” of the [log 2 (L)] bit is the buffer index.

The character buffer match/mismatch determination unit 33 then reads the [log 2 (X_{S})] bit (S607). X_{S} is the depth (number of tiers) of the character buffer 35 with buffer index “S”, and the value “T” of the [log 2 (X_{S})] bit is the index of character buffer 35 with buffer index “S”, i.e., the string index. The string Z stored in the entry with index “T” in the character buffer 35 with buffer index “S” is the string that matches the mismatch character string of the dictionary compression.

The character buffer 35 with buffer index “S” moves the character string Z stored in the entry with index “T” to the entry with index “0” (S608). At that time, the character buffer 35 with buffer index “S” shifts the character strings stored in the entries from index “0” to index “T−1” so that the index becomes +1 (S609).

The character buffer 35, which stores m character strings, stores the string Z in the entry with index “0” (S612). At that time, the character buffer 35 which stores m character strings shifts all stored strings so that the index becomes +1 (S613).

As described above, in the memory system 1 of the third embodiment, the compressor 114 includes character buffers 23 for each number of characters of the mismatch character string of dictionary type compression. The decompressor 115 also includes character buffers 35 for each number of characters of the mismatch character string of dictionary type compression.

This allows the memory system 1 of the third embodiment to improve compression efficiency by eliminating such problems as frequently appearing character strings being driven out of the character buffer 23 and character buffer 35 by less frequently appearing character strings.

### Fourth Embodiment

Next, the fourth embodiment will be explained.

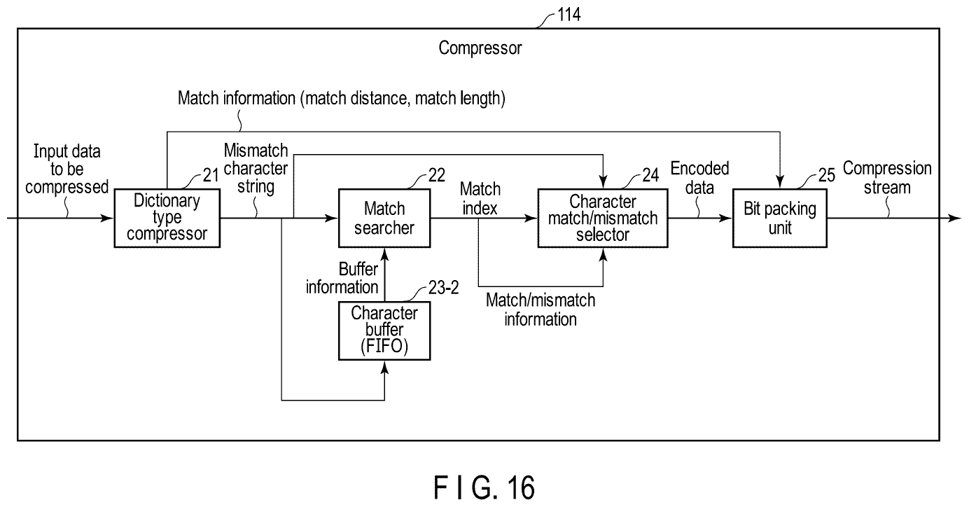

FIG. 16 is a diagram showing an example of a configuration of the compressor 114 in the memory system 1 of the fourth embodiment.

As shown in FIG. 16, the compressor 114 of the fourth embodiment includes a first in first out (FIFO) character buffer 23-2.

In the first embodiment, if the mismatch character string in the dictionary compression matches one of the strings in character buffer 23, the string is moved to the entry with index “0”. On the other hand, in the fourth embodiment the string is stored in the entry with index “0” regardless of whether or not the mismatch character string in the dictionary compression matches one of the strings in the character buffer 23-2.

In other words, the character buffer 23-2 of the fourth embodiment mechanically stores the mismatched character string of the dictionary type compression at the index “0” entry, even if the character string matching the mismatched character string of the dictionary type compression exists in the character buffer 23-2, thus storing of the same character string in a duplicating manner.

Although the presence of the same character string in the character buffer 23-2 wastes a few entries, if the string appears further as a mismatch character string of dictionary type compression, the comparison is completed when the string stored in the entry with the smaller index is detected, thus there is little degradation in compression efficiency.

On the other hand, the memory system 1 of the fourth embodiment can reduce costs because the character buffer 23-2 can be easily updated, leading to a reduction in the circuit size of the character buffer 23-2.

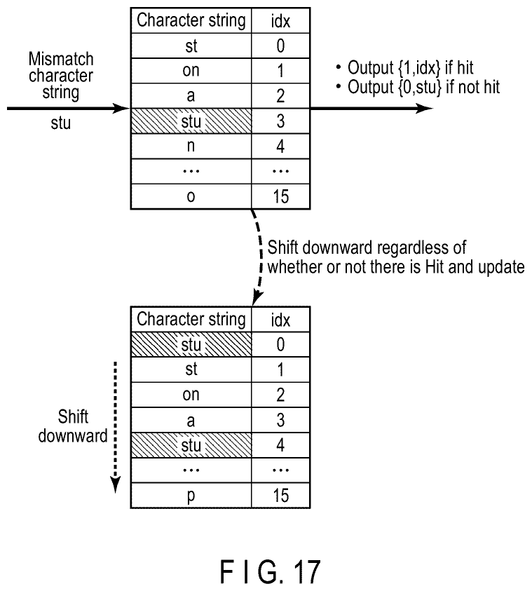

FIG. 17 is a diagram showing a concept of updating the character buffer of the memory system of the fourth embodiment.

In FIG. 17, for example, if the mismatch character string in the incoming dictionary compression is “stu”, it is stored in the entry with index “3” in the character buffer 23-2, and is matched by comparison with the mismatch character string of the dictionary compression. However, the character buffer 23-2 of the fourth embodiment shifts all stored strings so that the index becomes +1, and stores “stu” in index “0”. At this time, “stu” at index “3” becomes index “4” and “stu” is stored in both index “0” and index “4” in duplication.

If “stu” is entered as the next mismatch character string of dictionary type compression, the index “0” with the smaller value will be selected.

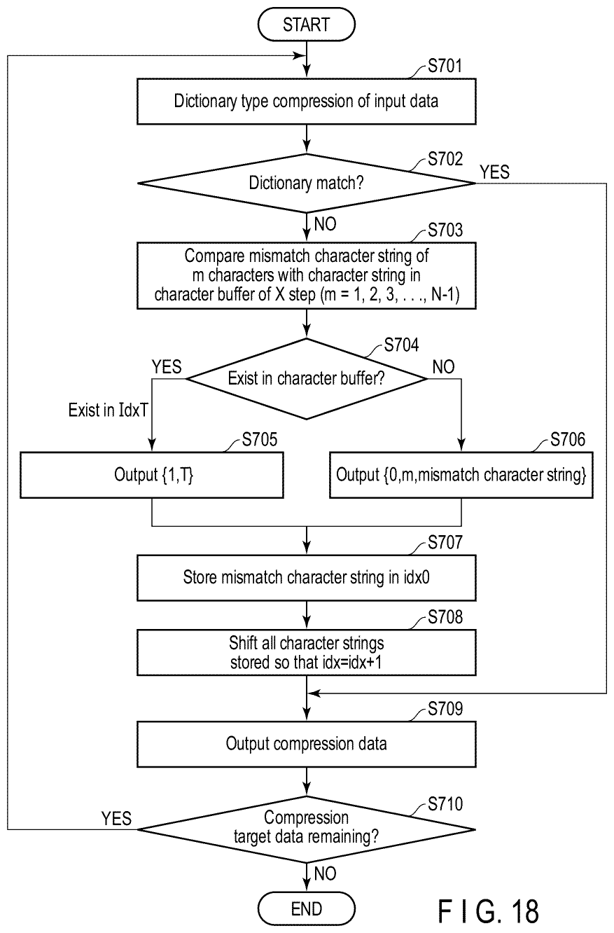

FIG. 18 is a flowchart showing an operating procedure of the compressor 114 in the memory system 1 of the fourth embodiment.

Only the parts (S707 and S708) which differ from the first embodiment (FIG. 5) will be explained here.

The character buffer 23-2 stores the mismatch character string of the dictionary compression at index “O” regardless of whether or not the mismatch character string exists in the character buffer 23-2 (S707). At that time, the character buffer 23-2 shifts all stored character strings so that the index becomes +1 (S708).

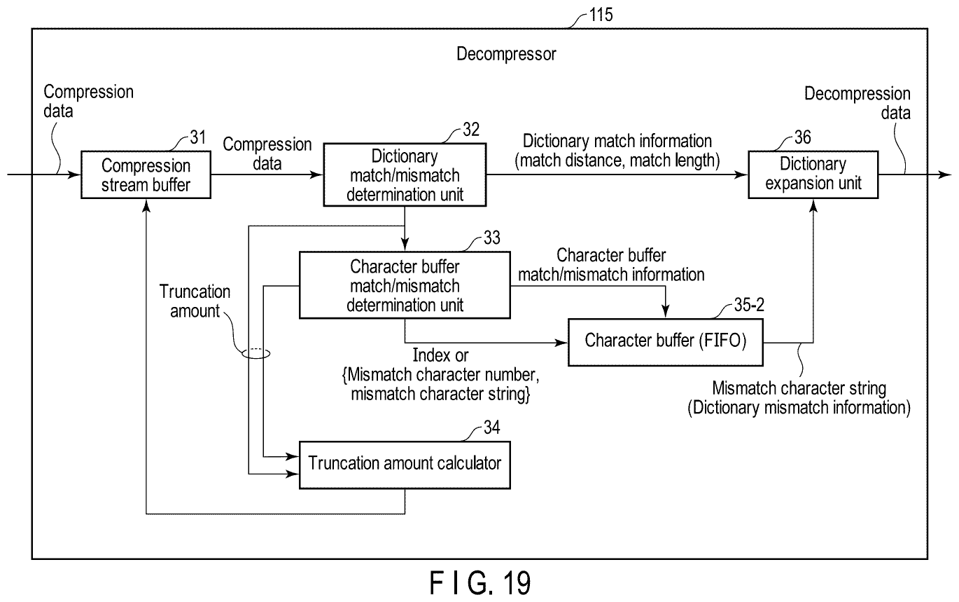

FIG. 19 is a diagram showing an example of a configuration of the decompressor 115 in the memory system 1 of the fourth embodiment.

As shown in FIG. 19, the decompressor 115 of the fourth embodiment, like the compressor 114, also has a FIFO-based character buffer 35-2.

In the character buffer 35-2 of the fourth embodiment, if the character buffer match/mismatch information received from the character buffer match/mismatch determination unit 33 is “1”, the other data received from the character buffer match/mismatch determination unit 33 is the index of character buffer 35-2. In this case, the character buffer 35-2 reads a character string from the entry at the index and outputs it to the dictionary type decompression unit 36 as a mismatched character string of dictionary type compression. In addition, the character buffer 35-2 separately stores the mismatch character string of dictionary type compression that already exists in the character buffer 35-2 at index “0” and shifts the other strings so that the index becomes +1.

If the character buffer match/mismatch information received from the character buffer match/mismatch detector 33 is “0”, the other data received from the character buffer match/mismatch detector 33 is a mismatch character string of dictionary type compression. In this case, the character buffer 35-2 outputs the mismatch character string of the dictionary type compression to the dictionary type decompression unit 36. Furthermore, the character buffer 35-2 stores the mismatch character string at index “0” and shifts the other strings so that the index becomes +1.

By using the FIFO method for the character buffer 35-2 of the decompressor 115, the size of the circuit for the character buffer 35-2 can also be reduced, leading to cost reduction.

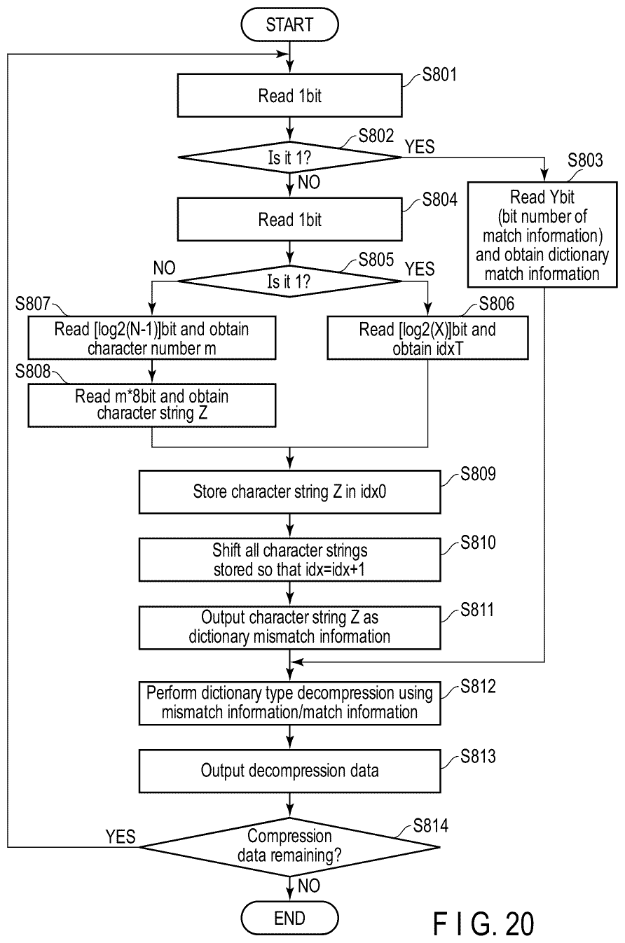

FIG. 20 is a flowchart showing an operating procedure of the decompressor 115 of the memory system 1 of the fourth embodiment. Here, only the parts (S806 to S810) which differ from the first embodiment (FIG. 8) will be explained.

The character buffer 35-2 stores the mismatched character string of dictionary type compression (S806) retrieved from the character buffer 35-2 by obtaining the index from the compressed data or the mismatched character string of dictionary type compression (S807, S808) retrieved from the character buffer 35-2, regardless of whether the mismatched character string of dictionary type compression matches any character string in the character buffer 35-2 or not, at index “0” (S809). At that time, the character buffer 35-2 shifts all stored character strings so that the index becomes +1 (S810).

As described above, the memory system 1 of the fourth embodiment uses FIFO type buffers for both the character buffer 23-2 of the compressor 114 and the character buffer 35-2 of the dictionary type decompression unit 36, thereby reducing the circuit size, and the cost.

### Fifth Embodiment

Next, the fifth embodiment will be explained.

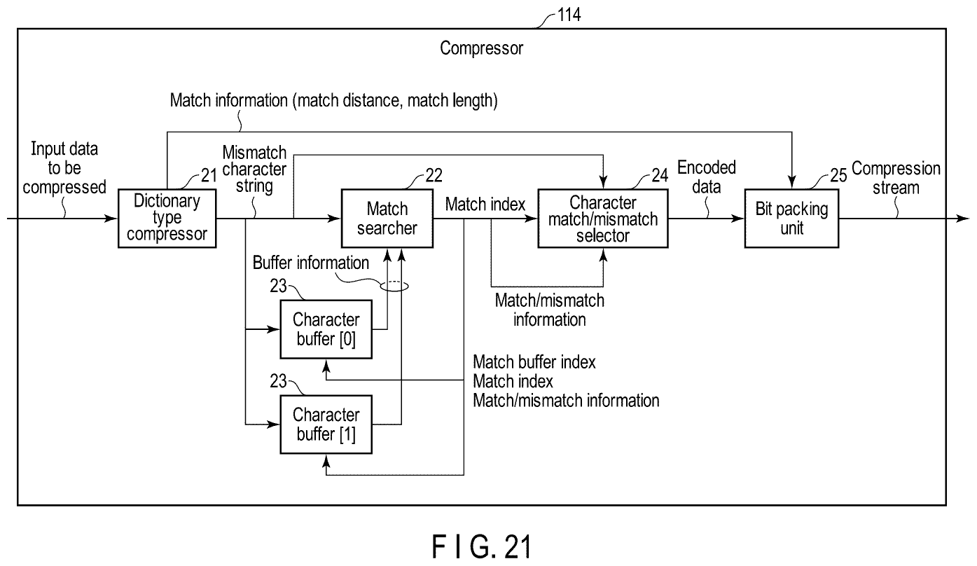

FIG. 21 is a diagram showing an example of a configuration of the compressor 114 in the memory system 1 of the fifth embodiment.

As shown in FIG. 21, the compressor 114 of the fifth embodiment includes a plurality of character buffers 23. Here, an example where two character buffers 23 are provided: character buffer [0]23 and character buffer [1]23 is used.

The compressor 114 of the third embodiment also includes multiple character buffers 23, but the compressor 114 of the third embodiment includes a character buffer 23 for each number of characters in the mismatch character string of dictionary type compression. In other words, the compressor 114 of the third embodiment uses different character buffers 23 for each number of characters in the mismatch character string of dictionary type compression. In contrast, the compressor 114 of the fifth embodiment uses multiple character buffers 23 in a time-divisional manner.

The character buffer 23 performs updating such as storing the mismatch character string of the dictionary compression at index “0” or moving the string to index “0” if there is a string which matches the mismatch character string of the dictionary compression. Until this update is completed, it is not possible to determine whether or not the next mismatch character string in the dictionary compression matches.

Therefore, for example, if there are two character buffers 23, the compressor 114 of the fifth embodiment uses these two character buffers 23 alternately in a time-divisional manner, and during the period when one character buffer 23 is being updated, the other character buffer 23 is referred to in the mismatch determination, so that the next mismatch determination does not wait for the completion of the update of the character buffer 23. Even if the update of the character buffer 23 has not been completed at the time the next mismatch decision is started, the reduction of the time to wait for the completion of the update of the character buffer 23 is achieved.

If the character buffer [0]23 of the fifth embodiment is referred by the match searcher 22 at a certain time t, the character buffer [0]23 is updated for the mismatch character string (t) of the dictionary type compression in two cycles at time t and t+1.

Similar to the character buffer [0]23, if the character buffer [1]23 of the fifth embodiment is referred from the match searcher 22 at a certain time t, the character buffer [1]23 is updated for the mismatch character string (t) of the dictionary type compression in two cycles at time t and t+1.

The match searcher 22 of the fifth embodiment switches timing of referring to character buffer [0]23 or character buffer [1]23 in an exclusively selective manner, depending on time. For example, if the match searcher 22 refers to the character buffer [0]23 at a certain time t, it refers to character buffer [1]23 at the next time t+1.

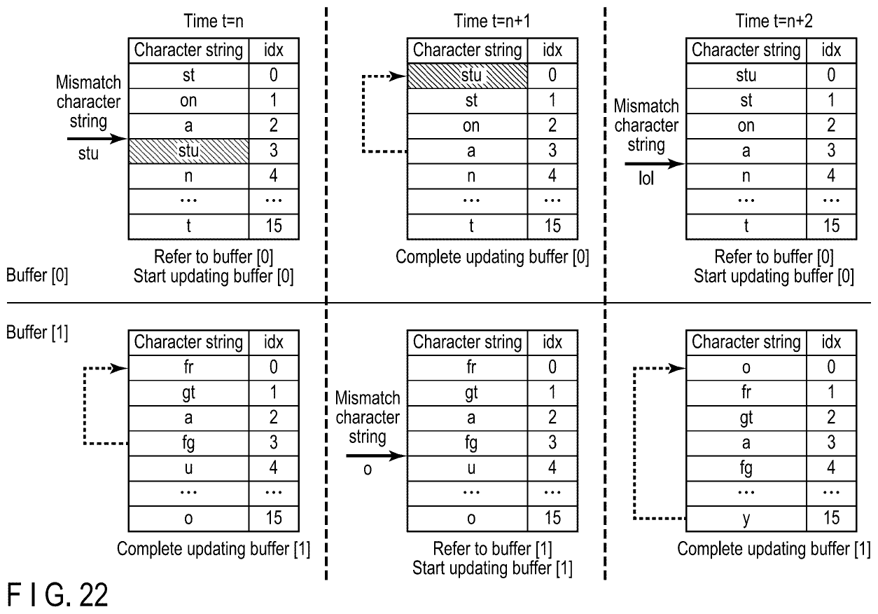

FIG. 22 a diagram showing a concept of updating the character buffer 23 in the memory system 1 of the fifth embodiment.

The compressor 114 of the fifth embodiment updates the character buffer 23 in two cycles.

For example, if at time t, the match searcher 22 uses the character buffer [0]23 to determine whether there is a match with the mismatch character string “stu” of the dictionary type compression, and based on the determination result, the character buffer [0]23 Starts updating the character buffer [0]23.

Meanwhile, at time t, the character buffer [1]23 completes updating related to the mismatch character string “ft” of the dictionary compression input at time t−1. At the next time t+1, the character buffer [0]23 completes updating related to the mismatch character string “stu” of the dictionary compression, and the character buffer [1]23 starts updating related to the mismatch character string “0” of the dictionary compression.

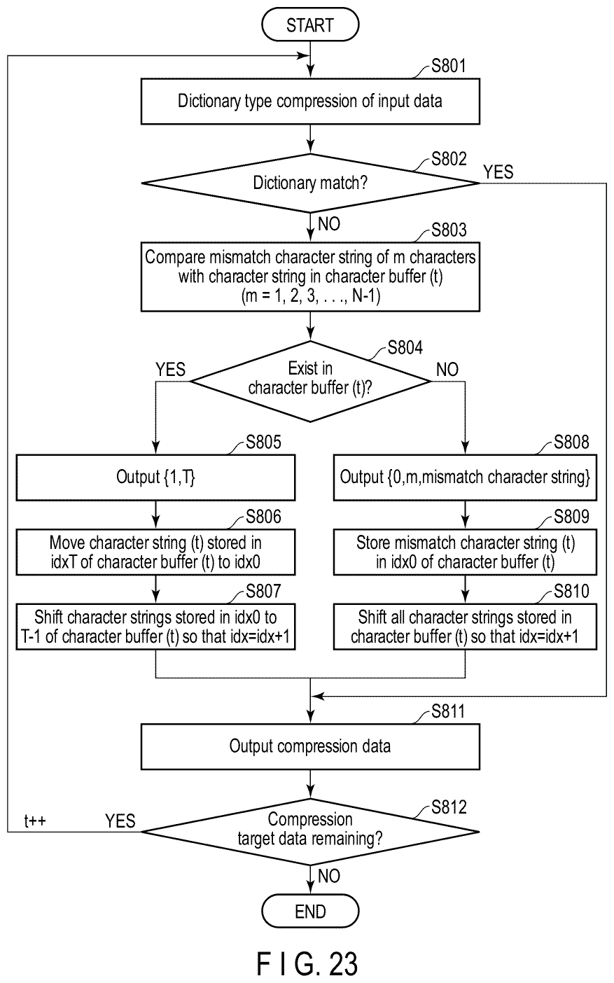

FIG. 23 is a flowchart showing an operating procedure of the compressor 114 of the memory system 1 of the fifth embodiment. Here, only the parts (S803, S806, S807, S809, and S810) which differ from the first embodiment (FIG. 5) are explained.

The match searcher 22 compares the mismatch character strings of the dictionary type compression of m characters with the strings in the character buffer (t) 23 (S803). The character buffer (t) 23 is the character buffer 23 applicable to time t.

If a mismatch character string of dictionary compression exists in the character buffer (t)23, the character buffer (t)23 shifts the mismatch character string of dictionary compression to index “0” (S806). At that time, the character buffer (t)23 shifts the strings from index “0” to index “t−1” so that the index becomes +1 (S807).

If the mismatch character string of dictionary compression does not exist in the character buffer (t)23, the character buffer (t)23 stores the mismatch character string of dictionary compression at index “0” (S809). At that time, the character buffer (t) 23 shifts all stored strings so that the index becomes +1 (S810).

Without waiting for the completion of updating the character buffer (t)23 in S806 and S807 or S809 and S810, the compressor 114 increments (+1) t and starts the process from S801 if there remains data to be compressed.

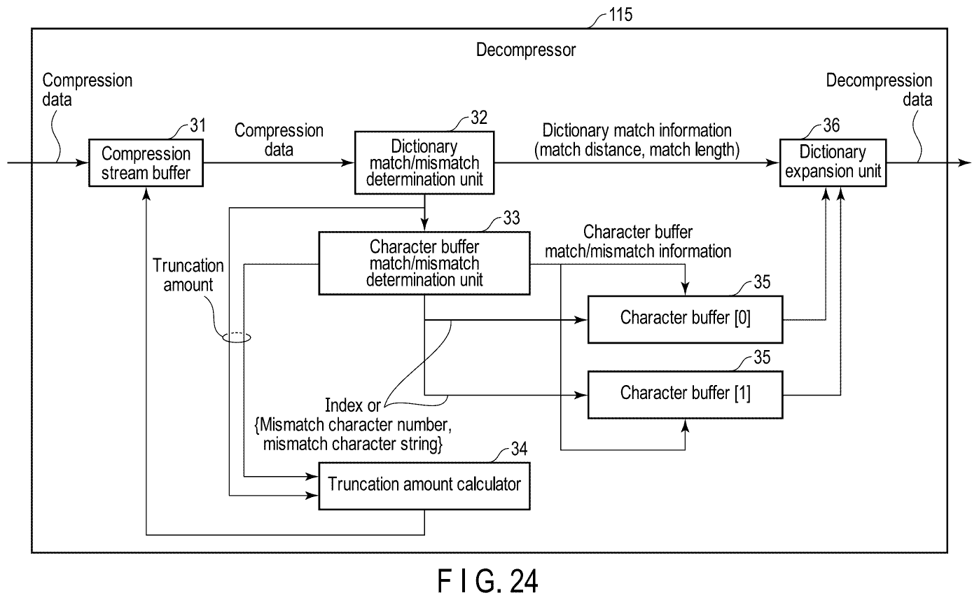

FIG. 24 a diagram showing an example of the configuration of the decompressor 115 of the memory system 1 of the fifth embodiment.

As shown in FIG. 24, the decompressor 115 of the fifth embodiment also includes two character buffers 23: character buffer [0]23 and character buffer [1]23. As with the compressor 114, the decompressor 115 of the fifth embodiment also alternates between the two character buffers 23 in a time-divisional manner.

The character buffer match/mismatch determination unit 33 of the fifth embodiment switches the timing of outputting character buffer match/mismatch information, etc., in an exclusively selective manner to character buffer [0]35 or character buffer [1]35, depending on time. For example, if the character buffer match/mismatch determination unit 33 outputs character buffer [0]23 at a certain time t, it outputs to character buffer [1]23 at the next time t+1.

If character buffer [0]35 of the fifth embodiment receives character buffer mismatch information, etc., from the character buffer match/mismatch determination unit 33 at a certain time t, it updates the character buffer [0]35 for the mismatch character string (t) of the dictionary type compression in two cycles at time t and t+1.

Similar to the character buffer [0]35, if receiving character buffer mismatch information, etc., from the character buffer match/mismatch determination unit 33 at a certain time t, at time t, t+1, in two cycles, the character buffer [1]35 of the fifth embodiment performs updating of the character buffer [1] 35 for mismatch character string (t) of the dictionary type compression.

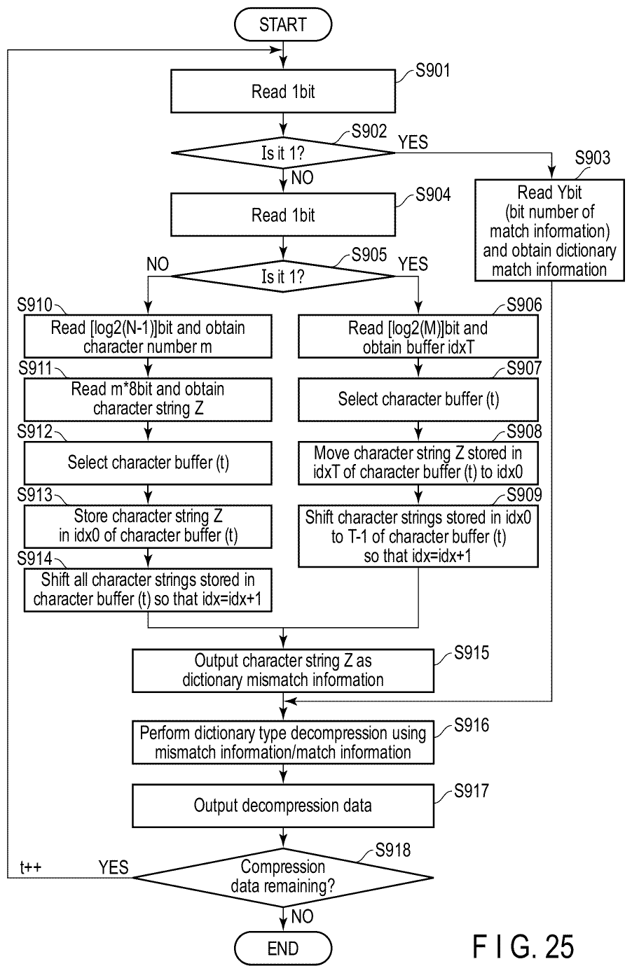

FIG. 25 is a flowchart showing an operating procedure of the decompressor 115 of the memory system 1 of the fifth embodiment. Here, only the parts (S907 to S909 and S912 to S914) which differ from the first embodiment (FIG. 8) will be explained.

The character buffer match/mismatch determination unit 33 selects the character buffer (t) 35 to obtain the character string Z from the index obtained from the compressed data (S907). The character buffer (t) 35 is the character buffer 35 applicable to time t.

The character buffer (t) 35 moves the character string Z stored in the entry with index “T” to the entry with index “0” (S908). At that time, the character buffer (t) 35 shifts the character strings stored in the entries from index “0” to index “T−1” so that the index becomes +1 (S609).

The character buffer match/mismatch determination unit 33 selects a character buffer (t) 35 storing the mismatch character string Z of the dictionary type compression obtained from the compressed data (S912).

The character buffer (t) 35 stores the string Z in the entry with index “0” (S913). At that time, the character buffer (t) 35 shifts all stored strings so that the index becomes +1 (S914).

Without waiting for updating the character buffer (t) 23 in S908 and S909 or waiting for completion of updating the character buffer (t) 23 in S913 and S914, the decompressor 115 increments (+1) t and starts the process from S901 if compressed data remains.

As described above, in the memory system 1 of the fifth embodiment, the compressor 114 and decompressor 115 include a plurality of the character buffers 23 and 35, thereby eliminating or greatly reducing the time spent waiting for the completion of updating the character buffer 23.

The description is shown here an example of two character buffers 23 and 35, but it is possible to have three or more character buffers 23 and 35 to ensure that updating of character buffers 23 and 35 is completed within a time limit which does not generate a waiting period.

Thus, the memory system 1 of the fifth embodiment can improve response performance in addition to increasing compression efficiency.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method of controlling a nonvolatile memory, the method comprising:
outputting information as compressed data, the information indicating a result of comparison between an input string of a predetermined length or longer and a string which has appeared previously;
storing data based on the output compressed data in the nonvolatile memory;
identifying an input string of less than the predetermined length as a mismatch character string;
determining whether or not the identified mismatch character string matches one of the mismatch character strings in the buffer where the mismatch character strings that have appeared previously are stored;
storing, as to the identified mismatch character string matching any of the mismatch character strings in the buffer, data based on a first data set including flag information indicating a match and index information indicating the entry of the buffer in which the mismatch character string determined to be a match is stored, in the nonvolatile memory; and
storing the identified mismatch character string which does not match any of the mismatch character strings in the buffer in the buffer, and storing, as to the identified mismatch character string, data based on a second data set including flag information indicating the mismatch and the identified mismatch character strings, in the nonvolatile memory.

2. The method of claim 1, wherein
an index is assigned in ascending order from a first entry to last in the buffer, and
the method further comprising updating the buffer so that a mismatch character string in the buffer which is determined to match the identified mismatch character string is moved to the first entry, and index corresponding to the mismatch character string stored in each entry from the first entry to the entry one before the entry in which the mismatch character string which is determined to match is stored is moved down by one.

3. The method of claim 2,
wherein the storing of the identified mismatch character string which does not match any of the mismatch character strings in the buffer to the buffer further comprises
storing the identified mismatch character string in the first entry by moving down an index corresponding to the mismatch character string stored in each entry of the buffer by one.

4. The method of claim 1, wherein
the buffer is configured to store a predetermined number of mismatch character strings, and
the predetermined number of characters is (the predetermined length−1).

5. The method of claim 1, wherein
the second data set includes the number of characters in the identified mismatch character string,
the number of characters of the identified mismatch character string is an integer between 1 to (the predetermined length−1),
the determination of whether or not the string matches one of the mismatch character strings in the buffer includes determining one of the (the predetermined length−1) buffers according to the number of characters in the identified mismatch character string, and
the first data set includes an identification number which uniquely identifies each of the (the predetermined length−1) buffers.

6. The method of claim 1, further comprising storing the identified mismatch character string in the first entry of the buffer.

7. The method of claim 1, further comprising:
using a plurality of the buffers alternately in a time-divisional manner; and
determining, while updating a first buffer in the buffers based on a first mismatch character string which is the identified mismatch character string, whether or not a second mismatch character string which is the identified mismatch character string and is identified following the first mismatch character string matches any of the mismatch character strings in a second buffer in the buffers that is different from the first buffer.

8. A compression encoder comprising:
a dictionary type compression circuit configured to output, when a length of an input string is longer than a predetermined length, information indicating a result of comparison between the input string and a string which has appeared previously as compressed data, and output, when the length of the input string is less than the predetermined length, the input string as a mismatch character string;
a buffer configured to store the mismatch character string; and
a match searching circuit configured to determine whether or not a mismatch character string output from the dictionary type compression circuit matches one of the mismatch character strings in the buffer by referring to the buffer, wherein
the match searching circuit is further configured to
output, when a mismatch character string output from the dictionary type compression circuit matches one of the mismatch character strings in the buffer, a first data set including flag information indicating the match, and index information indicating the entry in the buffer where the mismatch character string determined to be a match is stored as the compressed data,
output, when the mismatch character string output from the dictionary type compression circuit does not match any of the mismatch character strings in the buffer, the mismatch character string output from the dictionary type compression circuit to the buffer, and output a second data set including flag information indicating the mismatch and the mismatch character string output from the dictionary type compression circuit as the compression data, and
the buffer is configured to store the mismatch character strings output from the match searching circuit, which is and from the dictionary type compression circuit.

9. The compression encoder of claim 8, wherein
the match searching circuit is further configured to output the index information of the first data set to a buffer,
the buffer is assigned indexes in ascending order from a first entry to last, and
the buffer is further configured to move the mismatch character string stored in the entry corresponding to the index information in the first data set to the first entry, and move down the index corresponding to the mismatch character string stored in each entry from the first entry to the entry one before the entry indicated by the index information by one.

10. The compression encoder of claim 9,
wherein the buffer is configured to store, when storing a mismatch character string output from the match searching circuit, the mismatch character string output from the match searching circuit in the first entry by moving down the index corresponding to the mismatch character string stored in each entry of the buffer by one.

11. The compression encoder of claim 8, wherein
the buffer is configured to store a predetermined number of characters of the mismatch character string, and
the predetermined number of characters is (the predetermined length−1).

12. The compression encoder of claim 8, wherein
the second data set output as compressed data from the match searching circuit includes the number of characters in the mismatch character string output from the dictionary type compression circuit,
the number of characters of the mismatch character string output from the dictionary type compression circuit is 1 to (the predetermined length−1),
the compression encoder includes the (the predetermined length−1) buffers, and
the match searching circuit is further configured to
determine one of the (the predetermined length−1) buffers according to the number of characters in the mismatch character string output from the dictionary type compression circuit, and
set an identification number uniquely identifying each of the (the predetermined length−1) buffers in the first data set.

13. The compression encoder of claim 8,
wherein the buffer is further configured to store the mismatch character string output from the match searching circuit in the first entry, regardless of whether or not the mismatch character string output from the match searching circuit matches any of the mismatch character strings in the buffer.

14. The compression encoder of claim 8, further comprising a plurality of the buffers,
wherein the match searching circuit is further configured to
use the buffers alternately in a time-divisional manner, and
while updating a first buffer in the buffers based on a first mismatch character string, which is a mismatch character string output from the dictionary type compression circuit, use a second buffer in the buffers, determining whether or not the second mismatch character string which is a mismatch character string output from the dictionary type compression circuit and following the first mismatch character string matches one of the mismatch character strings in the second buffer, which is different from the first buffer in the buffers.

15. The compression encoder of claim 14, wherein
the second mismatch character string is the mismatch character string output from the dictionary type compression circuit following the first mismatch character string,
the updating of the first buffer includes,
when the second mismatch character string output from the dictionary type compression circuit before the first mismatch character string output from the dictionary type compression circuit matches one of the mismatch character strings in the buffer, moving the mismatch character string stored in the entry corresponding to the index information in the first data set corresponding to the second mismatch character string to the first entry, and moving down the index corresponding to the mismatch character string stored in each entry from the first entry to the entry one before the entry indicated by the index information by one, and
when the second mismatch character string does not match any of the mismatch character strings in the buffer, moving down the index corresponding to the mismatch character string stored in each entry of the buffer by one and storing the second mismatch character string in the first entry.

16. The compression encoder of claim 8,
wherein the information includes information indicating a position of the character string in the dictionary in which the character string which appeared previously is stored and information indicating a match length.

17. A memory system comprising:
a nonvolatile memory; and
a memory controller configured to control the nonvolatile memory, including a compression encoder of claim 8,
wherein the memory controller is further configured to input the character string to the dictionary type compression circuit and stores data based on the compressed data output from the compression encoder in the non-volatile memory.

18. A compression and decompression system comprising:
a compression encoder of claim 8; and
a decompression device configured to decompress compressed data compressed by the compression encoder, wherein
the decompression device comprises
a dictionary type decompression circuit,
a character buffer match/mismatch determination circuit configured to obtain the first or second data set from the compressed data, and
a second buffer configured to store the mismatch character string,
the second buffer is assigned indexes in ascending order from a first entry to last, and
the second buffer is further configured to
when the index information contained in the first data set is output from the character buffer match/mismatch determination circuit, output the mismatched character string stored in the entry indicated by the index information to the dictionary type decompression circuit as a character string to be decompressed, move the mismatch character string stored in the entry indicated by the index information to the first entry, and move down the index corresponding to the mismatch character string stored in each entry from the first entry to the entry one before the entry indicated by the index information by one, and
when a mismatch character string in the second data set is output from the character buffer match/mismatch determination circuit, output the mismatch character string to the dictionary type decompression circuit as a string to be decompressed, and moving down the index corresponding to the mismatch character string stored in each entry of the second buffer by one and storing the mismatched character string output from the character buffer match/mismatch determination circuit in the first entry.

19. A compression and decompression system comprising:
a compression encoder of claim 12; and
a decompression device configured to decompress compressed data compressed by the compression encoder, wherein
the decompression device comprises
a dictionary type decompression circuit,
a character buffer match/mismatch determination circuit configured to obtain the first data set or the second data set from the compression data, and
the (the predetermined length−1) buffers storing the mismatch character string,
each of the (the predetermined length−1) second buffers is assigned an identification number to be uniquely identified,
each of the (the predetermined length−1) second buffers is assigned index in ascending order from a first entry to last,
each of the (the predetermined length−1) second buffers is configured to
when the identification number and the index information contained in the first data set are output from the character buffer match/mismatch determination circuit, determine whether the identification number indicates itself or not, and when it indicates itself, output the mismatched character string stored in the entry indicated by the index information to the dictionary type decompression circuit as the character string to be decompressed, move the mismatched character string stored in the entry indicated by the index information to the first entry, and move down the index corresponding to the mismatch character string stored in each entry from the first entry to the entry one before the entry indicated by the index information by one, and
when the number of characters of the mismatch character string in the second data set and the mismatch character string are output from the character buffer match/mismatch determination circuit, determine whether or not the mismatch character string should be stored by itself based on the number of characters of the mismatch character string, and when it should be stored, output the mismatch character string as the string to be decompressed to the dictionary type decompression circuit, and move down the index corresponding to the mismatch character string stored in each entry by one and to store the mismatch character string to the head entry.

20. A compression and decompression system comprising:
a compression encoder of claim 13; and
a decompression device configured to decompress compressed data compressed by the compression encoder, wherein
the decompression device comprises
a dictionary type decompression circuit,
a character buffer match/mismatch determination circuit configured to obtain the first data set or the second data set from the compression data, and
a second buffer configured to store the mismatch character string, wherein
the second buffer is assigned indexes in ascending order from a first entry to last,
the second buffer is further configured to
when the index information contained in the first data set is output from the character buffer match/mismatch determination circuit, output the mismatched character string stored in the entry indicated by the index information to the dictionary type decompression circuit as the character string to be decompressed, move the mismatched character string stored in the entry indicated by the index information to the first entry, and move down the index corresponding to the mismatch character string stored in each entry of the second buffer by one, and
when the mismatch character string contained in the second data set is output from the character buffer match/mismatch determination circuit, output the mismatch character string as the string to be decompressed to the dictionary type decompression circuit, and move down the index corresponding to the mismatch character string stored in each entry of the second buffer by one and to store the mismatch character string to the head entry.

21. A compression and decompression system comprising:
a compression encoder of claim 14; and
a decompression device configured to decompress compressed data compressed by the compression encoder, wherein
the decompression device comprises
a dictionary type decompression circuit,
a character buffer match/mismatch determination circuit configured to obtain the first data set or the second data set from the compression data, and
a second buffer configure to store the mismatch character string,
the character buffer match/mismatch determination circuit is configured to
use the multiple second buffers alternately in a time-divisional manner, and
while updating a first buffer of the buffers based on the first data set or the second data set obtained at the first timing, output to a second buffer of the buffers, the index information contained in the first data set obtained at the second timing following the first timing, or the mismatched character string contained in the second data set.
